(19) United States
(12) Patent Application Publication
(10) Pub. No.: US 2024/0125865 A1
(43) Pub. Date: Apr. 18, 2024

(54) Systems and Methods for Pulse-Injection Diagnostics and Prognostics for Lithium-Ion Batteries

(71) Applicant: The Trustees of Columbia University in the City of New York, New York, NY (US)

(72) Inventors: Alan Gen Li, New York, NY (US); Alan C. West, New York, NY (US); Matthias Preindl, New York, NY (US)

(21) Appl. No.: 18/376,576

(22) Filed: Oct. 4, 2023

Related U.S. Application Data
(60) Provisional application No. 63/412,941, filed on Oct. 4, 2022.

(51) Int. Cl. G01R 31/392; G01R 31/367; G01R 31/3835

(52) U.S. Cl. CPC G01R 31/392; G01R 31/367; G01R 31/3835

(57) ABSTRACT

Disclosed are systems, methods, and other implementations, including a method for managing battery performance that includes measuring voltage response data for a lithium-ion battery in response to a current pulse perturbation injected into the lithium-ion battery, and determining in real-time, based on the measured voltage response data, resultant degradation data representative of estimated physical degradation of the lithium-ion battery.

### CROSS-REFERENCE TO RELATED APPLICATIONS

This application claims the benefit of, and priority to, U.S. Provisional Application No. 63/412,941, entitled “SYSTEMS AND METHODS FOR PULSE-ANALYSIS OF LITHUIM-ION BATTERIES” and filed Oct. 4, 2022, the content of which is incorporated herein by reference in its entirety.

### BACKGROUND

Non-invasive and minimally-disruptive lithium-ion battery (LIB) characterization is key to effective battery management. Though advances in LIB diagnostics have enabled real-time state-of-charge (SoC) estimation, capacity fade estimation with state-of-health (SoH) typically requires longer time scales. Furthermore, LIB degradation results from numerous coupled internal and external mechanisms that cannot be easily observed with non-invasive techniques. This causes considerable uncertainty in estimating the instantaneous degradation rate.

### SUMMARY

The present disclosure is directed to a proposed battery performance management framework that uses a current pulse perturbation to obtain quantities that reflect the degradation history and trajectory in a LIB cell. The cell's voltage response to the pulse is fed to a specially- trained machine learning (ML) system (e.g., a neural network, or NN), which then outputs the desired quantities. The proposed framework also implements an approach for collection and processing of ML system training data. Data collection is performed using experiments and simulations. There are 3 repeated stages of data collection: (1) steady-state diagnostics, (2) pulse train, and (3) aging protocol. In each stage various sensors are used (e.g., voltage, current, temperature). This data is processed to obtain target quantities such as the state of charge, state of health, state of power, remaining useful life, loss of lithium inventory, and loss of active material. Processing methods include coulomb counting, incremental capacity calculation, and half-cell modelling. Tests of the proposed framework demonstrate that it has at least 99% accuracy and could be applied to any cell chemistry at any combination of states. It has the potential to greatly simplify battery diagnostics and reduce costs and extend lifetimes in battery packs. The proposed framework can be used in applications such as electric vehicles and grid storage.

Thus, in some variations, a method for managing battery performance is provided that includes measuring voltage response data for a lithium-ion battery in response to a current pulse perturbation injected into the lithium-ion battery, and determining in real-time, based on the measured voltage response data, resultant degradation data representative of estimated physical degradation of the lithium-ion battery.

Embodiments of the method may include at least some of the features described in the present disclosure, including one or more of the following features.

The method may further include generating battery diagnostic and management data based on the resultant degradation data.

Determining the resultant degradation data may include determining incremental capacity (IC) behavior for the lithium-ion battery based on the voltage response data provided to at least one trained machine learning (ML) engine implementing an IC prediction model.

The at least one ML engine may include one or more of, for example, a neural network (NN)-based implementation and/or a ridge-regression (RR)-based implementation.

The at least one ML engine may be trained using input training data records, provided to an input stage of the at least one ML engine, prepared from measured training voltage response data resulting from training current pulse perturbations injected into the lithium-ion battery, and IC target output data, representing ground truth output for the at least one ML engine, computed based on one or more pseudo-open-circuit voltage (pOCV) tests applied to the lithium-ion battery.

Determining the incremental capacity behavior may include determining, based on the measured voltage response data, peaks of IC curves representing the IC behavior for the lithium-ion battery.

Determining the resultant degradation data may include performing overpotential analysis according to a convolution-defined diffusion (CDD) model for the lithium-ion battery based on the measured voltage response data resulting from the current pulse perturbation injected into the lithium-ion battery.

Performing the overpotential analysis according to the CDD model for the lithium-ion battery may include determining parameters of a circuit equivalent model, the parameters being representative of electro-chemical attributes of the lithium-ion battery, and deriving one or more voltage components of the voltage response data based on the determined parameters.

The method may further include determining an impedance change behavior based on the derived one or more voltage components.

Determining the parameters representative of the electro-chemical attributes of the lithium-ion battery may include determining one or more of, for example, a series resistance equivalence parameter R₀, charge transfer equivalence parameters R_{N} and C_{N} for N≥1, and/or a diffusion related constant, A_{D}, for the lithium-ion battery at steady state.

The method may further include estimating one or more degradation modes for the lithium-ion battery based on the resultant degradation data determined from the measured voltage response data.

Estimating the one or more degradation modes may include estimating one or more of, for example, battery impedance change of the lithium-ion battery, loss of lithium inventory (LLI) of the lithium-ion battery, and/or loss of active material (LAM) of the lithium-ion battery.

The method may further include determining based on, at least in part, the estimated one or more degradation modes one or more of, for example, state of health (SoH) of the lithium-ion battery, state of charge (SoC) for the lithium-ion battery, and/or state of power (SoP) for the lithium-ion battery.

The current pulse perturbation may include one or more rectangle pulses applied to the lithium-ion battery for a duration of up to 3 minutes.

In some variations, a battery performance management system is provided that includes a sensor to measure voltage response data for a lithium-ion battery in response to a current pulse perturbation injected into the lithium-ion battery, and a processor-based controller, coupled to the sensor, configured to determine in real-time, based on the measured voltage response data, resultant degradation data representative of estimated physical degradation of the lithium-ion battery.

In some variations, a non-transitory computer readable media is provided that includes computer instructions executable on a processor-based device to measure voltage response data for a lithium-ion battery in response to a current pulse perturbation injected into the lithium-ion battery, and determine in real-time, based on the measured voltage response data, resultant degradation data representative of estimated physical degradation of the lithium-ion battery.

Embodiments of the system and the computer readable media may include at least some of the features described in the present disclosure, including at least some of the features described above in relation to the method.

Other features and advantages of the invention are apparent from the following description, and from the claims.

### BRIEF DESCRIPTION OF THE DRAWINGS

These and other aspects will now be described in detail with reference to the following drawings.

FIG. 1 is a diagram of an example framework for estimating battery attributes and managing battery performance.

FIG. 2 is another diagram of an example framework for estimating battery attributes (including estimating degradation modes) and for managing battery performance.

FIG. 3 is a circuit diagram of an example equivalent circuit model with a diffusion component and N resistor-capacitor (RC) pairs (DNRC).

FIG. 4 includes graphs showing comparisons of results obtained with a PBM model and a D1RC model for a cell.

FIG. 5 is a workflow diagram to implement an IC analysis for the proposed frameworks.

FIG. 6 includes Pseudo-OCV discharge and incremental capacity curves for cells degraded by two different sets of stress factors.

FIG. 7 includes graphs providing results for IC reconstruction.

FIG. 8 includes graphs providing sample prediction results of IC peaks for the stress factor of FIG. 7.

FIG. 9 includes graphs providing sample prediction results of IC peaks when using a ridge regression and neural network ML models.

FIG. 10 is a flowchart of an example procedure for managing battery performance, in part through monitoring battery degradation.

FIG. 11 includes graphs plotting the data collected from six cells used during testing and evaluation of the frameworks of FIGS. 1 and 2, including IC curves capacity fades, and voltage response harmonics.

FIG. 12 includes graphs showing prediction of SoH and SoC using different diagnostic features analyzed by a ridge regression ML model.

FIG. 13 includes graphs showing overpotential contribution percentages for various parameters, plotted against cycle number and SoC.

FIG. 14 includes graphs showing IC extrema identification according to ridge regression and neural network ML model.

FIG. 15 includes graphs showing reconstructed IC curves using extrema predictions.

FIG. 16 includes graphs showing IC peak identification using a ridge regression ML model and a neural network ML model.

FIG. 17 is a graph of proposed pulse shapes to apply to a cell.

FIG. 18 is a diagram of a proposed pulse scheduling framework for an electrical vehicle.

Like reference symbols in the various drawings indicate like elements.

### DESCRIPTION

A proposed framework is discussed that uses pulse perturbation to diagnose cell states, ion transport phenomena and electrode degradation in lithium-ion batteries (LIB). Degradation in lithium-ion batteries is traditionally characterized with the pseudo open-circuit voltage (pOCV) or incremental capacity (IC), but these methods have hours-long diagnostics times and cannot easily measure impedance change. The use of current pulses to measure the response of the battery and derive ion transport and electrode degradation diagnostics can exceed the capabilities of conventional degradation diagnostics, while requiring a fraction of the time. Under the proposed approach, linear combinations of the IC extrema and the pulse harmonics are shown to predict State of Health (SoH) and nominal State of Charge (SoC) for the battery determined with less than 1% and 6% error, respectively. Individual contributions of the ohmic, charge transfer, and diffusion overpotentials, as well as open-circuit voltage or hysteresis, can be derived through application of the current pulse. Neural networks, for example, reconstruct IC extrema from the pulse harmonics with less than 1% error. The pulse response reflects internal kinetic parameters and electrode phase transitions which are best uncovered using neural networks. The performance of the proposed framework extends the uses of pulsing and suggests novel methods for degradation diagnostics in battery management systems.

Conventionally, LIB degradation can be described using a multi-level framework containing metrics, modes, and mechanisms. Each level provides more powerful diagnostics and prognostics of degradation. In theory, the modes of capacity fade such as the loss of lithium inventory (LLI) or loss of active material (LAM) can be used to determine the future SoH trajectory more accurately than just the SoH prior history. Similarly, mechanisms such as solid-electrolyte interphase formation or particle fracture are good predictors of the modes. Open-circuit voltage (OCV) or pseudo-OCV (pOCV) methods are the conventional non-invasive laboratory technique for obtaining degradation modes and metrics. The pOCV curve is obtained by discharging the cell from 100% SoC at a low C-rate (the rate at which a battery is discharged relative to its maximum capacity) such as C/10 or C/20. This not only yields the cell SoH but also encodes information about the positive electrode (PE) and negative electrode (NE) phase transitions. Half-cell models show that LAM and LLI may be estimated entirely from the predicted electrode degradation. Underpinning the results from half-cell models is incremental capacity analysis (ICA). The IC curve is defined as the inverse-derivative of the pOCV with respect to remaining charge capacity. Phase transitions—plateaus in the pOCV—are represented by IC extrema. However, in many applications conventional pOCV and ICA diagnostics are too disruptive, and cannot be performed in real-time.

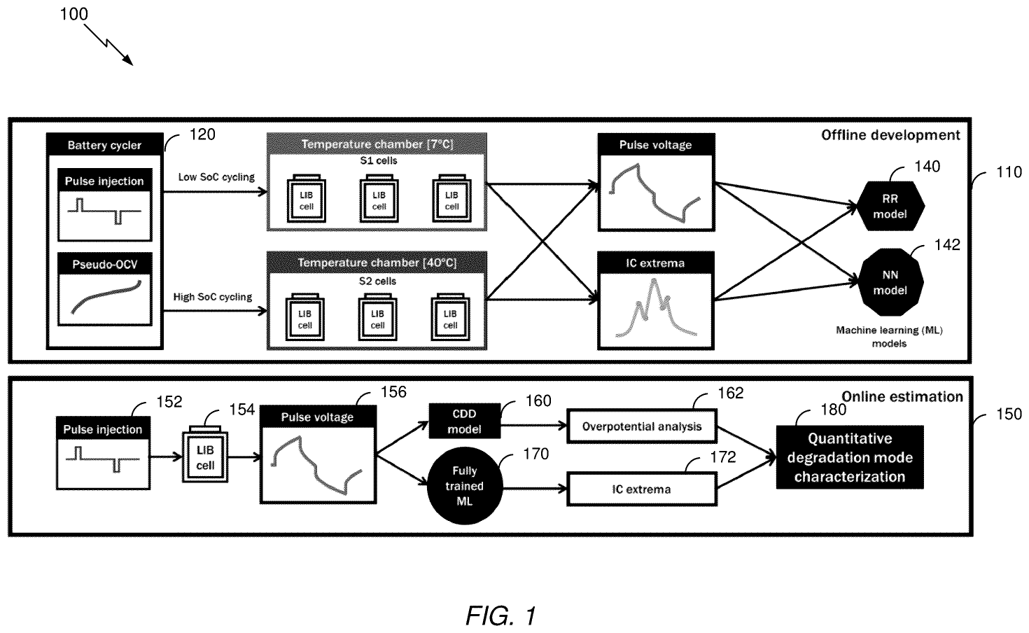

With reference to FIG. 1, a diagram of an example framework 100 for battery performance management and for estimating battery attributes (such as SoH, SoC, and various degradation modes for the battery) is shown. The framework includes an offline stage 110 and an on-line (runtime) stage 150. Under the proposed framework, and as will be discussed in greater detail below, a machine learning system, such as one implemented through an NN model 142 (which forms part of the ML models section 162 during execution of the runtime stage 150), or some other machine learning architecture, can be trained to accurately estimate cell states and even predict the lifetime of a LIB cell when trained on the cell's pulse voltage responses. The techniques described herein, named pulse-injection-aided machine learning (PIAML), are implemented through the ML model section 162, and are configured to uncover deeper levels of degradation beyond the metrics through analysis performed by the quantitative degradation mode characterization module 180. Under the proposed framework, during runtime a pulse voltage response (resulting from a current pulse sequence 152 applied to a lithium-ion-battery 154) encodes signatures from ion transport dynamics and electrode degradation. A convolution-defined diffusion (CDD) model 160 and the ML model section 170 implementing the PIAML procedures are used to extract overpotential contributions (e.g., through an overpotential analysis module 162), SoC, SoH, and IC features (optionally derived through an IC extrema module 172 depicted in FIG. 1 when applied to IC curve output data produced by the ML model section 170, or derived at the module 180). Experimentation results have shown that the CDD model and PIAML are sufficient to characterize degradation modes in LIB cells.

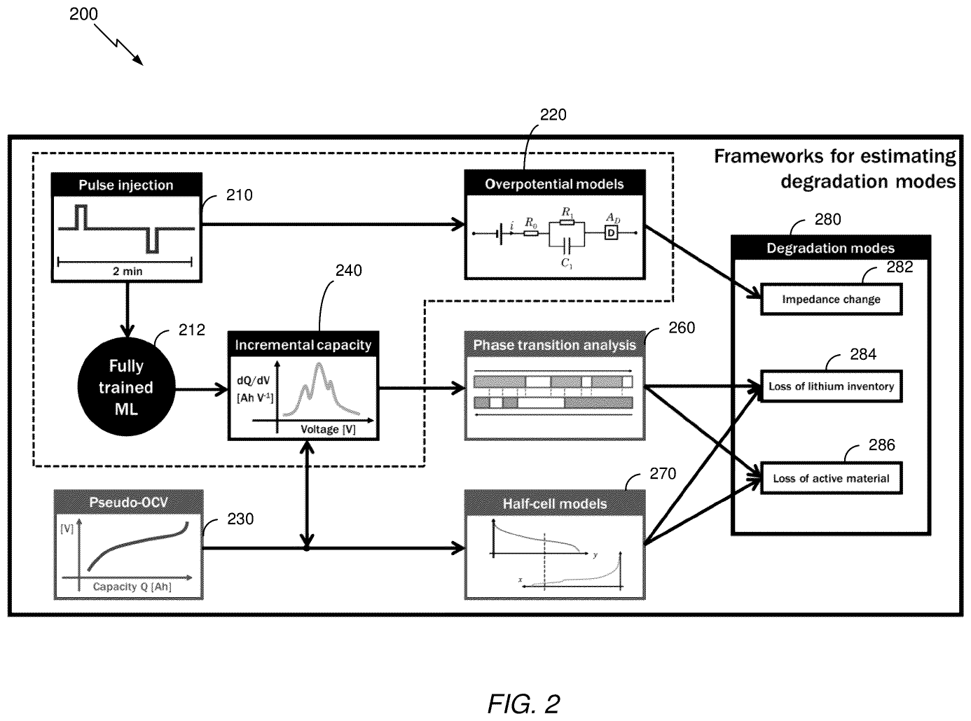

With reference to FIG. 2, another illustrative diagram 200 of the framework for battery performance management estimating lithium ion battery attributes (including estimating degradation modes for the LIB) is shown. The framework depicted in FIG. 2 may be configured similarly to the framework illustrated in FIG. 1, but provides some additional details not specifically illustrated in FIG. 1. As noted, under the proposed framework, a pulse injection is used to determine degradation modes for a lithium-ion battery, including SoC, SoH, SoP, LLM, LAM, etc.

As illustrated in FIG. 2, a pulse injection train 210 is applied to terminals of a lithium-ion battery, and results in a voltage response. Different pulses can be used to trigger the voltage response based on which degradation data is obtained. Pulses are defined by their shape, amplitude, bias, and length. Pulse shape affects the frequency content of the pulse which, following spectroscopy principles, determines the amount of encoded information. One type of pulse that can be used in conjunctions with the frameworks described herein are rectangle pulses, which have constant current charge or discharge. A variety of pulse amplitudes and biases were tested to examine the effects of pulse shape on PIAML performance. Pulses can be labelled according to an amplitude-bias ratio (ABR). Reducing the ABR allows the effects of ‘noise’ to be considered. ABR [dB] is given by

$$ABR = 20 log \frac{{I}_{A}}{{I}_{B}} ,$$

where I_{A} is the amplitude of the injected pulse current and I_{B} is the bias current. The overall input current to the cells i(t) over time t is the superposition of the constant bias I_{B} with the pulse shape iₚ, i(t)=I_{A}iₚ(t)+I_{B}. The bias acts as a source of noise which obfuscates iₚ. Hysteresis from an incompletely rested cell could also act as a time-varying bias, reducing the ABR.

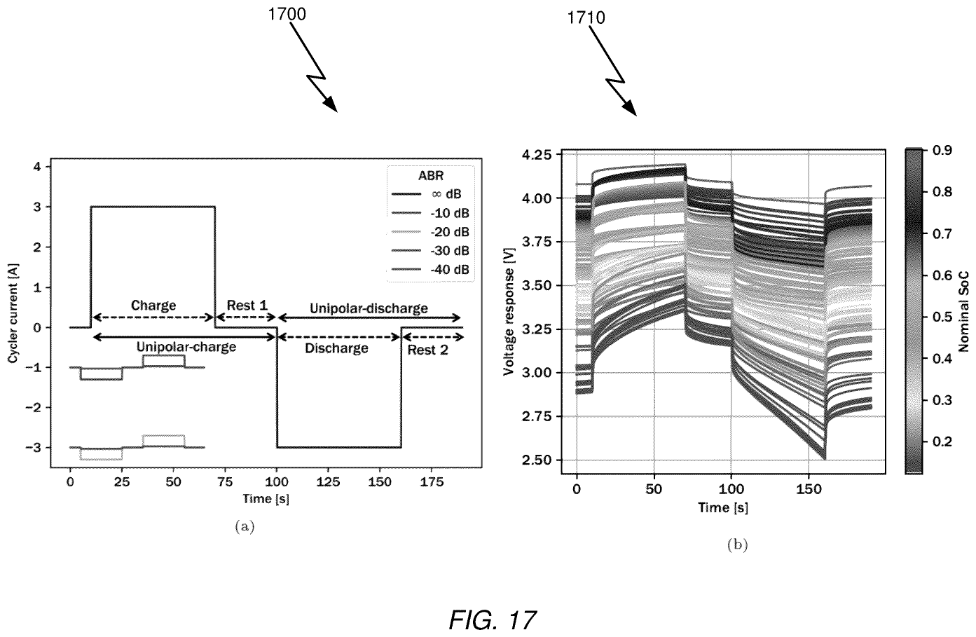

A suitable pulse shape to apply to the cell is a ∞ ABR pulse, shown in graph 1700 of FIG. 17, in which there are four individual portions named ‘Charge’, ‘Rest 1’, ‘Discharge’, and ‘Rest 2’, each lasting 60 s or 30 s (the voltage response to the ∞ ABR pulse is depicted in graph 1710). The two unipolar portions are named ‘Unipolar-charge’ and ‘Unipolar-discharge’ and last 1.5 min. The Unipolar-charge portions are preferably applied after a 1 hour rest, after which the cell hysteresis voltage has dissipated. Unipolar-discharge portions, however, are applied after a 30 s rest period. This means that the hysteresis voltage remains significant.

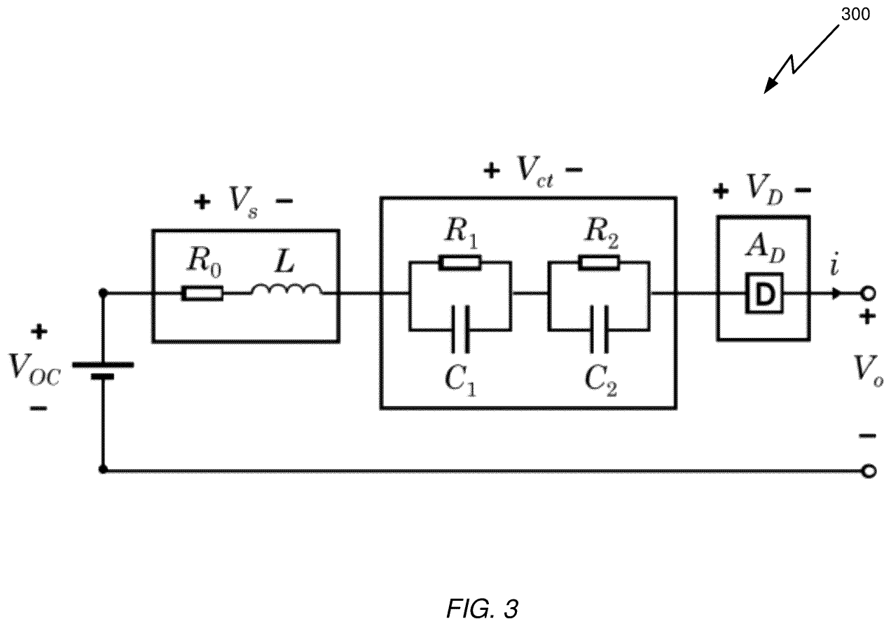

With continued reference to FIG. 2 (and as also illustrated in FIG. 1), the voltage response data captured from the lithium-ion battery is provided to one or more overpotential models realized at module 220 (CDD model module 160 in FIG. 1, which are configured to, in part, determine impedance data for the cell). An example of a model that may be used in conjunction with the proposed framework 200 is a battery equivalent circuit model (ECM) comprising a physics-based diffusion component and N resistor-capacitor (RC) pairs (this model is thus referred to as DNRC). The DNRC model characterizes ohmic, charge transfer, and diffusion overpotentials in the time-domain with four (4) impedance parameters: R₀, R₁, C₁, and A_{D}. With reference to FIG. 3, a circuit diagram of an example DNRC model 300 is shown. In the example of FIG. 3, N=2, and therefore the circuit model is referred to as D2RC. It is to be noted that in the example of FIG. 2, the example circuit model shown as implemented by the overpotential model module 220 there is a single pair of RC elements (used, in some situations, to represent of a single cell), and accordingly that circuit model is referred to as D1RC.

The proposed model is represented in FIG. 3, with output voltage Vₒ given by:

Vₒ(t)=V_{OC}(t)−Vₛ(t)−V_{ct}(t)−V_{D}(t) (1)

where V_{OC} is the OCV, and Vₛ, V_{ct}, and V_{D} are the solution, charge transfer, and diffusion overpotentials voltage. The model is referred to as the DNRC model because it combines the elements of an NRC model with a newly-proposed diffusion element. As noted, it is renamed after the number of RC-pairs included, e.g., D1RC for 1 pair, D2RC for 2 pairs, etc. Each labelled voltage is linked to an electrochemical overpotential. The discrete-time expression is formulated using sampling interval Δt and time step tₖ, with initial conditions being from rest.

The OCV, represented is the terminal voltage of the battery cell Vₒ after sufficient rest. The OCV is known to vary significantly with SoC and slightly with SoH. OCV is estimated directly from the cell current, with no fitting parameters. There are many approaches to OCV estimation. An example of an estimation approach for V_{OC} is obtained with a simple recursive definition, as follows:

$${V}_{OC} ( {t}_{K + 1} ) = ( \frac{\partial {V}_{OC}}{\partial SoC} {\vert}_{SoC ( {t}_{k} )} ) \frac{i ( {t}_{k} ) ηΔ t}{{Q}_{m}} + {V}_{OC} ( {t}_{k} ) \qquad ( 2 )$$

where ∂V_{OC}/∂SoC is calculated offline, i is the cell current, η is the coulombic efficiency, Δt=tₖ₊₁−tₖ is the sampling interval, and Qₘ is the maximum capacity of the cell.

The solution overpotential, represented by Vₛ, is the ohmic voltage developed across the electrodes, electrolyte, and contacts. Typically Vₛ captures high-frequency (e.g., above 100 Hz) behavior in the cell. It is modelled using a resistor and an inductor, and governed by the following equation:

$${V}_{s} ( t ) = {R}_{0} i ( t ) + L \frac{di}{dt} \qquad ( 3 )$$

where i(t) is the cell current, R₀ is a series resistance, and L is an inductor. Using zero-order hold (ZOH) discretization results in:

$${V}_{s} ( t ) = \frac{{R}_{0} ( i ( {t}_{k + 1} ) - i ( {t}_{k} ) {e}^{- \frac{Δ {tR}_{0}}{L}} )}{1 - {e}^{- \frac{Δ {tR}_{0}}{L}}} \qquad ( 4 )$$

It is to be noted that it is generally inappropriate to include the inductor when the data sampling frequency is below 100 Hz. This is because the inductor's effects are not observed at lower sampling frequencies. When this is the case, we L can be approximated to be L→0, which results in Vₛ(tₖ)=R₀i(tₖ).

The charge-transfer overpotential, represented by V_{ct}, models overpotentials from multiple phenomena in the cell that act from 1 to 100 Hz. The RC-pairs are related to the double-layer capacitance and charge migration at the electrodes and at the solid-electrolyte interphase (SEI) layer. Each RC-pair is governed by the equation:

$$i ( t ) = {i}_{Rn} ( t ) + {R}_{n} {C}_{n} \frac{{di}_{Rn}}{dt} \qquad ( 5 )$$

where iRₙ is the current through the resistor Rₙ, and Cₙ is the capacitance. Using ZOH, the discrete-time form gives:

$${i}_{Rn} ( {t}_{k} ) = {i}_{Rn} ( {t}_{k} ) {e}^{- \frac{Δ t}{{R}_{n} {C}_{n}}} + i ( {t}_{k} ) ( 1 - {e}^{- \frac{Δ t}{{R}_{n} {C}_{n}}} ) \qquad ( 6 )$$

Thus, the voltage V_{ct} is given by:

$${V}_{ct} ( {t}_{k} ) = {\sum }_{n = 1}^{N} {R}_{n} {i}_{Rn} ( {t}_{k} ) \qquad ( 7 )$$

The diffusion overpotential V_{D} models the voltage generated by the transport of Li-ions from concentration gradients in the cell, which is observed at low frequencies under 1 Hz. Stress-induced diffusion, though important, is assumed to be negligible compared to concentration gradients. The voltage V_{D} is derived assuming semi-infinite diffusion for a solid electrode. Electrode structure effects are not considered. Fick's law for diffusion is then given by:

$$\frac{\partial {c}_{s}}{\partial t} = \frac{D}{x} \frac{\partial }{\partial x} ( {x}^{2} \frac{\partial {c}_{s}}{\partial x} ) \qquad ( 8 )$$

where cₛ and D are the concentration and diffusion coefficient of lithium in the active material and x is a length vector across the electrode. Note that x=0 represents the electrolyte-electrode interface and x=L represents the electrode-collector interface.

Consider first the diffusion overpotential from a single current step. Using the conditions

$${c}_{s} ( x , t = 0 ) = {c}_{s , 0} \\ \frac{\partial {c}_{s}}{\partial x} {\vert}_{x = L} = 0 \\ D \frac{\partial {c}_{s}}{\partial x} {\vert}_{x = 0} = \frac{Δ I}{{q}_{e} S} \qquad ( 9 )$$

and assuming that t_{D}<<L²/D, it can be shown that:

$$\frac{{dc}_{s} ( x = 0 , t )}{d \sqrt{t}} = \frac{2 Δ I}{{q}_{e} S \sqrt{D π}} \qquad ( 10 )$$

governs behavior over a single current step, where c_{s,0} is the initial concentration, assumed constant across the electrode, ΔI is the value of the current step, t_{D} is the step duration, S is the active surface area of the electrode, and qₑ is the elementary charge. Concentration is proportional to change in the relative stoichiometry of lithium in the electrode δ, providing:

$${dc}_{s} = \frac{{N}_{A}}{{v}_{M}} d δ \qquad ( 11 )$$

which is then used to obtain the diffusion overpotential η_{D} using:

$$\frac{d {η}_{D}}{\partial \sqrt{t}} \frac{d δ}{d {η}_{D}} = \frac{2 Δ {I}_{{v}_{M}}}{SF \sqrt{D π}} \qquad ( 12 )$$

where v_{M} is the molar volume of active material, F is Faraday's constant, and N_{A} is Avogadro's number.

It can be shown that:

$$\frac{d {η}_{D}}{d δ} = β \frac{\partial {V}_{OC}}{\partial SoC} \qquad ( 13 )$$

where dη_{D}/dδ quantifies the change in overpotential due to the amount of stoichiometric added lithium, ∂V_{OC}/∂SoC is the derivative of the OCV-SoC curve, and β is a conversion factor.

Thus, the variation of diffusion overpotential over time from a single current step is given by:

$$\frac{d {η}_{d}}{d \sqrt{t}} = \frac{2 βΔ {I}_{{v}_{M}}}{SF \sqrt{D π}} \frac{\partial {V}_{OC}}{\partial SoC} \\ {η}_{D} = ( \frac{2 βΔ {I}_{{v}_{M}}}{SF \sqrt{D π}} \frac{\partial {V}_{OC}}{\partial SoC} ) \sqrt{t} \qquad ( 14 )$$

Defining

$${A}_{D} = \frac{2 {β}_{{v}_{M}}}{SF \sqrt{D π}}$$

yields:

$${η}_{D} = {A}_{D} Δ I ( \frac{\partial {V}_{OV}}{\partial SoC} ) \sqrt{t} \qquad ( 15 )$$

where A_{D} is the diffusion related constant for the cell at steady state.

To generalize this relationship for any number of current steps Nₚ, a diffusion state function ψₙ(t) is introduced for the n^{th} step change, given by:

$${ψ}_{n} ( t ) = Δ {I}_{n} ( \frac{\partial {V}_{OV}}{\partial SoC} {\vert}_{SoC ( {t}_{n} )} ) \sqrt{t - {t}_{n}} \qquad ( 16 )$$

where ΔIₙ is the value of the step change, tₙ is the time of the step change, and t≥tₙ. The overall diffusion voltage is given by the superposition of all ψₙ(t), yielding:

$${V}_{D} ( t ) = {A}_{D} {\sum }_{n = 1}^{{N}_{P}} {ψ}_{n} ( t ) \qquad ( 17 )$$

This shows that the voltage response at any time is composed of the superposition of all diffusion states from previous current steps. For discretization, consider the derivative,

$$\frac{d \sqrt{t - {t}_{n}}}{dt} = \frac{1}{2 \sqrt{t - {t}_{n}}} \qquad ( 18 )$$

By ZOH conditions, the discrete-time function is therefore given by:

$${ψ}_{n} ( {t}_{k + 1} ) = Δ {I}_{n} ( \frac{\partial {V}_{OC}}{\partial SoC} {\vert}_{SoC ( {t}_{n} )} ) \sqrt{H ( {t}_{k} - {t}_{n} ) ( Δ t + {ψ}_{n} ( {t}_{k} ) )} \qquad ( 19 )$$

where H is the Heaviside step function.

As noted, there are two initial processing steps for OCV and the diffusion states. In some embodiments, the derivative ∂V_{OC}/∂SoC is computed offline using pseudo-OCV data, obtained using a 0.1 C-rate discharge from 100 to 0% SoC. This is then used in Equation 2. The OCV is initialized with the cell voltage after a rest period. In practice, since it is not always possible to rest the cell, methods such as Kalman filters can be used.

To obtain the diffusion voltage as shown in Equation (19), step change times tₙ and step change values ΔIₙ must be calculated from the cell current. A new current step is defined when the observed cell current changes by more than by a small threshold Iₜₕᵣ over a single sampling interval. This is represented by the conditions expressed as follows:

$$if \{ \vert I ( {t}_{k} ) - I ( {t}_{k - 1} ) \vert > {I}_{thr} \\ then \{ \begin{matrix}{t}_{n} = {t}_{k} \\ Δ {I}_{n} = I ( {t}_{k} ) - I ( {t}_{k - 1} )\end{matrix} \qquad ( 20 )$$

When visualizing and analyzing results, it is useful to know the SoC and SoH. The D2RC does not use these states for modelling or fitting. SoC quantifies the remaining charge q in the cell relative to the maximum charge capacity of the cell Qₘ, given by

$$SoC = \frac{q}{{Q}_{m}} \qquad ( 21 )$$

The capacity Qₘ decreases as the cell degrades. SoH is defined as the normalized maximum capacity, or Qₘ relative to its initial value, namely:

$$SoH = \frac{{Q}_{m}}{{Q}_{m 0}} \qquad ( 22 )$$

Values for Qₘ and q are obtained from coulomb counting. Processing for SoC and SoH is performed offline, and is typically used only for providing a reference when plotting results.

The equivalent circuit model parameter identification and determination is performed with constrained function minimization. This can be implemented, in some embodiments, using MATLAB-based global optimization for non-convex functions, though many other approaches can be used instead. The problem statement is given by: minimize f(θ), subject to θ>0.

For a D2RC equivalent circuit (i.e., an equivalent circuit with two RC pairs, as depicted in the example circuit diagram 300 of FIG. 3), the following relationships are defined:

f(θ)=∥r∥₂²+a∥r′∥₂²

r(k)=y(tₖ)=ŷ(tₖ,θ)

r′(k)=r(k+1)−r(k)

θ=(R₀ R₁ R₂ C₁ C₂ A_{D})^{T} (23)

for all k=1, . . . , K, where there are K available data points, y and ŷ are the observed and predicted data, respectively, θ is the parameter vector, and the weighting coefficient a set to a=1.

The objective function f is composed of two terms: the sum of squared residuals (SSR)∥r∥₂², and the sum of squared residual differences (SSRD)∥r′∥₂². The SSR term minimizes the total tracking error. The SSRD term performs quadratic smoothing to avoid large spikes in prediction and increase agreement in curvature between the observed and predicted data. Since the OCV variation has no fitting parameters, the observed data is defined as,

y(t)=V_{OC}(t)−Vₒ(t) (24)

and the predicted data is given by,

ŷ(t,θ)=Vₛ(t)+V_{ct}(t)+V_{D}(t) (25)

Data predictions are defined with the discrete-time expressions, as derived above, and can be represented in state form as follows:

$$( \begin{matrix}{V}_{s} ( {t}_{k + 1} ) \\ {V}_{ct} ( {t}_{k + 1} ) \\ {V}_{D} ( {t}_{k + 1} )\end{matrix} ) = ( \begin{matrix}{R}_{0} i ( {t}_{k + 1} ) \\ {\sum }_{n = 1}^{2} {R}_{n} ( {i}_{Rn} ( {t}_{k} ) {e}^{- \frac{Δ t}{{R}_{n} {C}_{n}}} + i ( {t}_{k} ) ( 1 - {e}^{- \frac{Δ t}{{R}_{n} {C}_{n}}} ) ) \\ {A}_{D} {\sum }_{n = 1}^{{N}_{p}} Δ {I}_{n} ( \frac{\partial {V}_{OC}}{\partial SoC} {\vert}_{SoC ( {t}_{n} )} ) \sqrt{H ( {t}_{k} - {t}_{n} ) ( Δ t + {ψ}_{n} ( {t}_{k} ) )}\end{matrix} ) \qquad ( 26 )$$

Optimization also requires an initialization of the parameter vector. This is accomplished with reasonable guesses of the expected magnitudes.

Thus, the DNRC (also referred to as CDD-NRC, with N representing the number of equivalent RC pairs) equivalent circuit model captures electrochemical overpotential behavior, including solution voltage, charge transfer, and diffusion, using a series resistor, RC-pairs, and a novel diffusion element. The DNRC ECM can be implemented in discrete-time state-space form, allowing for real-time estimation. Three-fold validation with experimental and physics-based models (PBM), which simulated data, showed that DNRC ECM parameters (and in this example, the D2RC RCM parameters) not only yield high accuracy predictions, but are also linked to internal cell states.

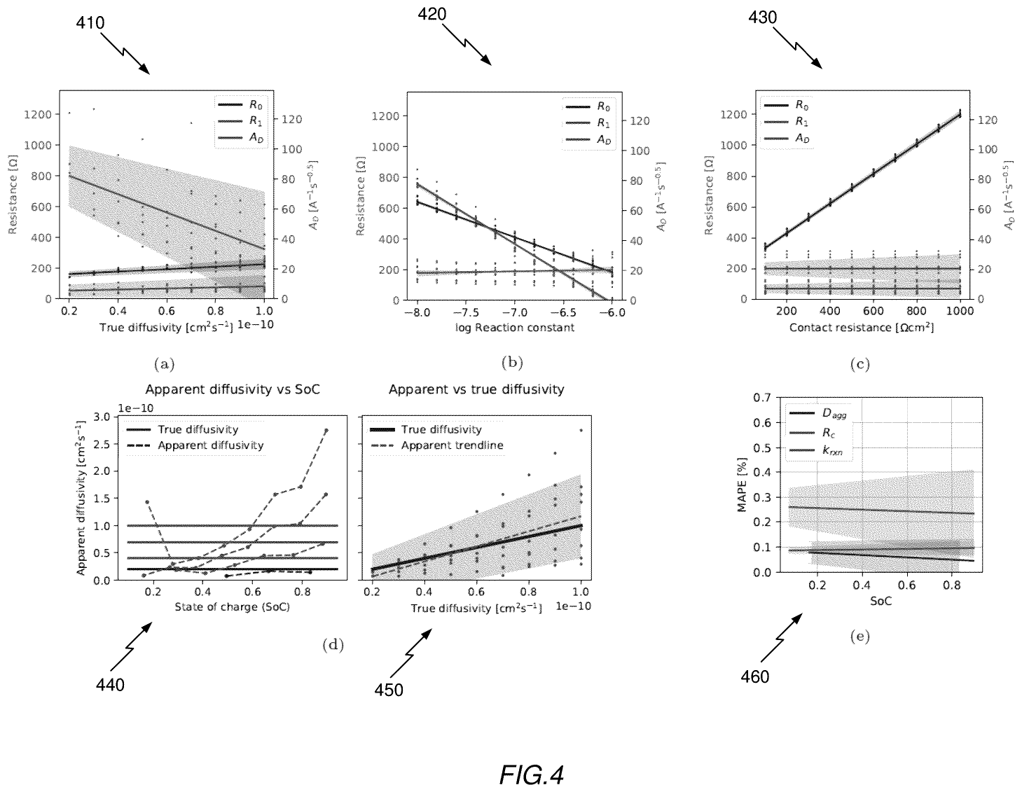

Specifically, with reference to FIG. 4, graphs showing comparisons of results obtained with a cell's PBM model and a D1RC model (similar to the one used in conjunction with the frameworks of FIGS. 1 and 2) are provided. The graphs of FIG. 4 include three graphs displaying the variation of D1RC parameters with internal PBM states. Specifically, graph 410 plots variation of estimated D1RC parameters against varying true diffusivity, graph 420 plots variation of estimated D1RC parameters against varying reaction constant, and graph 430 plots variation of estimated D1RC parameters against contact resistance. FIG. 4 further includes a graph 440 of the apparent diffusivity extracted from the D1RC model against SoC for selected values of true diffusivity, and a graph 450 of the apparent diffusivity extracted from the D1RC model plotted against the true diffusivity. Finally, a graph 460 provides a comparison of the MAPE of the voltage predictions. As the graphs illustrate, there is good agreement between the D1RC predicted voltage and the PBM generated voltage, with average MAPE (mean absolute percent error) being below 0.5%.

There are clear and distinct trends in the D1RC parameters for each dataset. When diffusivity is varied, correlation is strong with A_{D} but negligible with R₀ and R₁. When the reaction constant is varied, correlation is strong with R₀ and R₁ but negligible with A_{D}. When contact resistance is varied, correlation is very strong with R₀, and negligible with R₁ and A_{D}. The results in FIG. 4 show that the effects of individual cell states can be captured by the D1RC model. As expected, the novel diffusion element is most correlated with the varying diffusivity, and R₀ is most correlated with the contact resistance. Varying the reaction constant, however, has more complex effects on the voltage response that cannot be captured by a single circuit element. It is correlated with both the charge transfer and solution overpotentials.

As noted, in the graphs 440 and 450 of FIG. 4 apparent diffusivity \hat{D} is compared with true diffusivity D_{agg}, plotted against both SoC and D_{agg}. Unlike D_{agg}, which does not vary with SoC, \hat{D} does vary with SoC. This may be due to SoC-varying states in the PBM, such as initial concentration, that are not accounted for by elements in the D1RC model. The trend line of \hat{D} is highly correlated with D_{agg}, showing good agreement between the apparent and true diffusivities.

It is to be noted that PBM values are derived directly from physical principles governing the electrochemical processes occurring in battery cells. Due to the complexity of battery cells, PBM are typically composed of more than fifty (50) parameters, which may not be known in non-laboratory environments, and are governed by numerous coupled partial differential equations. Although PBM is very accurate, and the parameters are fully interpretable because they are linked directly to the cell structure and chemistry, the complexity of the models makes PBM estimation very time-consuming. Because of this, PBM can be used to gain insight into degradation processes in the cell. However, the DNRC ECM provides a simple and fast method to track battery degradation processes using time-domain data.

The DNRC models may be able to show that different battery cycling conditions, such as extreme temperatures, high C-rates, or extreme SoC, yield different signatures in the parameter evolution plots. Combined with fast and accurate SoH estimation techniques, the DNRC ECM offers an attractive mechanism to be used in the BMS, as is done in the proposed frameworks depicted in FIGS. 1 and 2, to actively adjust battery pack performance to reduce degradation, thus allowing for new control methods.

Thus, and as depicted in FIGS. 1 and 2, the example frameworks (100 and 200) configured to determine the resultant degradation data (and to otherwise determine behavior attributes of the lithium-ion battery(ies) being monitored and managed) is configured to perform overpotential analysis according to a convolution-defined diffusion model for the lithium-ion battery based on the measured voltage response data resulting from the current pulse perturbation injected into the lithium-ion battery.

Turning back to FIG. 2, as shown, the framework uses machine learning engines (marked as ML module 212) to facilitate incremental capacity (IC) analysis performed by the module 240 of FIG. 2. While transient dynamics are well-captured, the CDD model yields little information about the steady-state OCV behavior. The OCV represents the equilibrium voltage attained by cell and is almost entirely determined by the lithiation of the two electrodes. As electrode lithiation fraction increases from 0 to 1, multiple phase transitions occur. Analysis of these transitions from the pOCV (performed by pOCV analysis module 230) and IC curves (as determined by the ML engine 212, by the analysis module 240, and optionally the downstream transition analysis module 260) yields LLI (represented by the box 284 of FIG. 2) and LAM (represented by box 286 of FIG. 2). By reconstructing the IC curve from pulsing, degradation diagnostics can be greatly simplified.

IC curves are traditionally obtained from battery cells by observing the voltage over a low C-rate discharge from full. This is known as the pseudo-open-circuit-voltage (pOCV) test or capacity check. Obtaining accurate pOCV measurements often requires a C/10 or C/20 discharge rate, meaning the test duration is ten to twenty hours. IC peak amplitudes represent phase changes due to the battery electrode dynamics and lithium inventory. Thus, while the evolution of the IC peaks due to degradation is not directly equal to the loss of active material or cyclable lithium, it is highly correlated. For this reason, pOCV and IC curves can support degradation modes estimation. Pulse perturbation is usually viewed as a characterization method for equivalent circuit models. As noted, pulses excite a wide range of frequencies in the battery that form the transient response, as opposed to the pOCV steady state response. A cell's voltage response to a current pulse thus encodes a wealth of information. The proposed frameworks (depicted in FIGS. 1 and 2) use PIAML (pulse-injection-aided machine learning), implemented at the ML module 212 of FIG. 2 for fast IC analysis. This approach reduces the IC analysis time to several minutes.

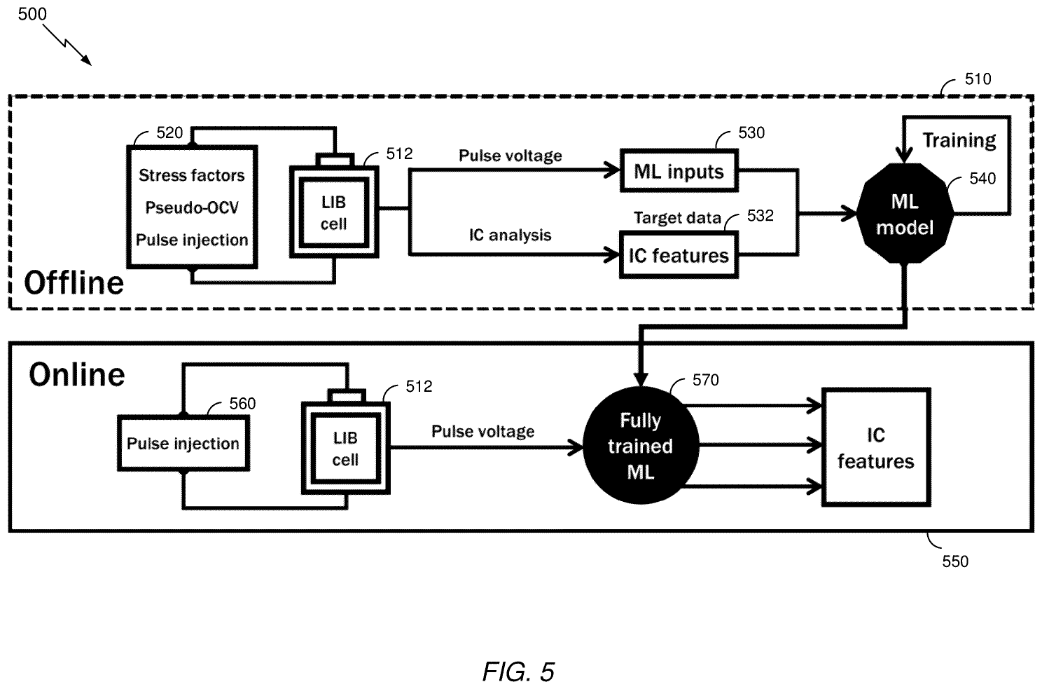

With reference next to FIG. 5, a workflow diagram 500 to implement the IC analysis for the proposed frameworks is shown. As illustrated, the workflow includes an offline stage 510 and an online (runtime) stage 550. The offline stage 510 includes a data collection module 520 through which the LIB cell 512 is subjected to various operational physical processes. These operational physical processes are defined through stress factor sets that correspond to cycling conditions, a pseudo OCT process to perform steady state analysis to facilitate capturing the IC behavior for the cell, and a pulse injection to obtain transient IC behavior for the cell. The application of the various stimuli at specified conditions results in the capture of data that includes a voltage pulse response (caused by applying the pulse injection by the module 520). Together with IC features determined through conventional IC analysis, e.g., using p-OCV testing, ML-based solutions for IC data computation can be developed (it is again to be noted that this part of the workflow is performed offline, when real-time data is not yet required). The voltage response represents the input data 530 to the ML model(s) 540 to be used, while IC features determined from the IC analysis represent the target data 532 (defining the ground truths for the ML models). These data records are then used to train the ML models 540.

In experimentation and evaluation of the IC analysis implementations of the framework, data collections and processing to train the ML models 540 proceeded as follows. Data was collected from six fresh nickel-magnesium-cobalt Panasonic NCR18650PF cells. Two sets of cycling conditions, known as stress factors, were applied to three cells each. In stress factor 1 (S1), cells were cycled at 8° C. from the lower cutoff 2.5 V to mid-voltage, while in stress factor 2 (S2) cells were cycled at 40° C. from mid-voltage to the maximum cutoff 4.2 V. Cycling rate was 2.7 A, corresponding to 1 Crate. Equal amounts of coulombs are passed in each cycle for both S1 and S2. Each stress factor affects how the state of health (SoH) changes over time. Result data showed that S1 stress factor degraded the cells much more quickly than S2.

Every 100 cycles, a pseudo-OCV C/20 discharge was performed. This was used to generate the IC curves and calculate the SoH, given by:

$$SoH = \frac{Q ( t )}{{Q}_{0}} \qquad ( 27 )$$

where Q is the maximum capacity at elapsed time t and Q₀ is the capacity at t=0. Both are obtained using coulomb counting over, for example, C/20 discharge rate. The IC is obtained by taking the inverse derivative of the pseudo-OCV Vₚₛ with respect to the instantaneous remaining battery capacity q [Ah], namely:

$$IC = \frac{dq}{{dV}_{ps}} \qquad ( 28 )$$

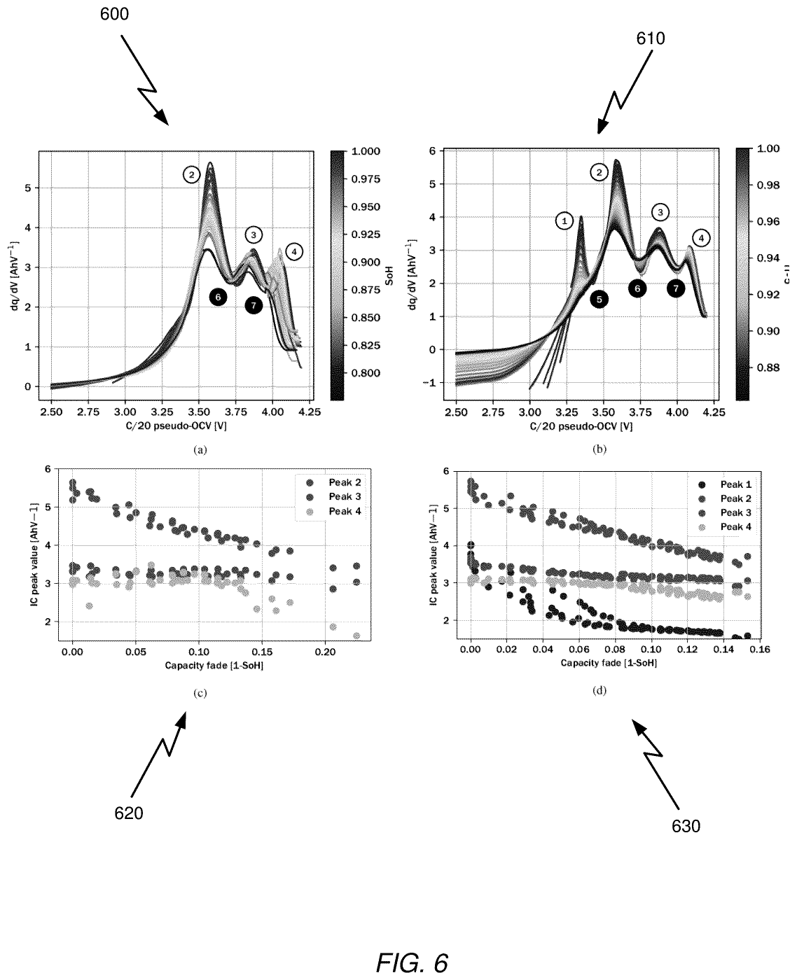

Capacity q is obtained using coulomb counting. A Savitzky-Golay filter is used for smoothing. The IC curves are then obtained by plotting IC against Vₚₛ. Peaks and troughs are key IC features. FIG. 6 shows the Pseudo-OCV discharge and incremental capacity curves of cells degraded by S1 (graph 600) and S2 (graph 610). The incremental capacity curves are labelled with peak numbers. FIG. 6 additionally includes evolution of incremental capacity curve peaks with respect to capacity fade (graph 620 corresponds to the S1 stress factor, and graph 630 corresponds to the S2 stress factor). As shown in FIG. 6, the peaks have especially strong and distinct trends with degradation. Different stress factors also result in different IC behavior. It can be seen that Peak 1 is non-existent for S1. Peak 4, at high voltage, degrades more rapidly after 10% capacity fade, which could be attributed to the positive electrode. Peaks 1 and 2 decay exponentially for the first 1% of capacity fade, then appear to follow a linear degradation rate. This may be due to solid-electrolyte interphase layer formation.

To reconstruct the key features of an IC curve, the troughs (labelled in black) are also needed. Thus, both IC peaks and extrema points are considered. This ensures that behavior within the active range of 3.25 V to 4.15 V is captured. S1 has 3 peaks and 5 extrema points while S2 results in 4 peaks and 7 extrema points.

Pulses are applied immediately after the capacity check, similarly to the galvanostatic intermittent titration technique (GITT) protocol. Two-minute long pulses were used. Pulse amplitude was 1 C-rate and divided into 4 equal charge, discharge, and rest portions. Pulses were applied from approximately 0.1 to 0.9 SoC, meaning each pulse corresponded to a unique combination of SoC and SoH. There were 363 pulses for S1 and 742 for S2. Since each pulse is applied to the cell at a specific cycle in the cell's degradation, they were linked to an IC curve. Multiple pulses are linked to a single IC curve due to varying SoC levels. When used as data inputs, the mean pulse voltage is subtracted to yield the voltage harmonics. This normalizes the dataset and removes the nominal OCV offset.

Two machine learning models (trained with the data produced through the data collection processes of the offline stage 510) were used to estimate the IC peaks or extrema given a pulse voltage response: ridge regression (RR) and feedforward neural network (NN). RR is much simpler and can be used to provide a ‘benchmark’ for the NN model. Both models were trained using 80% of the available data. The remaining 20% was then used to test the trained models on new unseen samples. The training dataset is represented using the matrix X∈ R^{N×P}:

$$X = ( \begin{matrix}- {x}_{1} - \\ {x}_{1} \\ ⋮ \\ {x}_{n}\end{matrix} ) \qquad ( 29 )$$

where xₙ ∈ R^{P} is a single voltage response, N is the number of training samples and P is the number of data points in the pulse, P=(pulse duration [s])/(sampling interval−0.1 s). The output dataset is represented using the matrix Y∈ R^{N×M}:

$$Y = ( \begin{matrix}\vert & \vert & & \vert \\ {y}_{1} & {y}_{2} & ⋯ & {y}_{M} \\ \vert & \vert & & \vert\end{matrix} ) \qquad ( 30 )$$

where yₘ ∈ R^{N} represents the data for the m^{th} output and M is the total number of target outputs for each sample. For example, when estimating the peaks of S1 data, M=3 because there are 3 peaks. Similarly, when estimating the extrema of S2 data, M=7 because there are 7 extrema points.

RR is an L2-regularized form of the basic least-squares regression algorithm that maximizes the posterior data distribution, with feature vector wₘ∈ R^{P} calculated from:

wₘ=arg min∥yₘ−Xwₘ∥²+λ∥wₘ∥² (31)

where λ=0.5 is the regularization parameter which may be further tuned to change the model performance RR yields an analytical solution to this minimization problem of:

wₘ=(λI+X^{T}X)⁻¹X^{T}yₘ (32)

The predicted output vector for an unseen pulse \hat{x}∈ R^{P} is then given by:)

ŷ_{RR}=\hat{x}^{T}W_{RR} (33)

where W_{RR} ∈ R^{P×M} is represented by:

$${W}_{RR} = ( \begin{matrix}\vert & \vert & & \vert \\ {w}_{1} & {w}_{2} & ⋯ & {w}_{M} \\ \vert & \vert & & \vert\end{matrix} ) \qquad ( 34 )$$

Neural networks are popular deep-learning models capable of learning complex relationships between data. A NN is generally composed of a large number of matrix multiplications defined by the number of hidden layers and nodes, node activations, network weights, and biases. Within each layer i the node output vector may be represented as

x [symbol] _{=σ(}W [symbol] x [symbol] ₋₁+b [symbol] ) (35)

where Wᵢ is the matrix of weights connecting each node in layer l−1 to layer l, xₗ₋₁ is the vector of outputs from the previous layer, bₗ is the bias vector, and σ is the activation function governing node behavior. Note that l=0 represents the input layer, equal to the pulse voltage vector. The final output predictions are then given by:

ŷ_{NN}=W_{L}x_{L}+b_{L} (36)

where L is the number of hidden layers.

The goal of NN training is to determine the optimal Wₗ and bₗ matrix for each hidden layer. This is performed using stochastic gradient descent and backpropagation process, which adjusts the weights based on the output at each training epoch. For validation, 20% training data was used, corresponding to 16% of the original dataset. This can help avoid overfitting. Many hyperparameters must be selected to determine NN performance Batch normalization is applied between each hidden layer to accelerate training and increase regularization.

Both RR and NN include multi-dimensional matrix transformations. There are many more NN parameters than there are in an RR feature matrix, thus increasing the NN's capabilities. This comes at the cost of longer training times, higher computational complexity, and lower interpretability. While each RR feature quantifies how important a specific sampling point of the pulse voltage is to the target output, NN features are usually considered a black-box.

In the proposed frameworks described herein, the ML model being implemented receives the vector of pulse voltage measurements as its input, and further receives the target IC output data defining the ground truths for the model (as illustrated in FIG. 5 at boxes 530 and 532, and at models node 540). In some example embodiment, the cycle number is not used (because cycles are not consistently defined or collected in real-world applications and different conditions may result in different degradation rates). The models were trained using single stress factor and combined stress factor data. When a single stress factor was considered, there was a consistent degradation rate. When datasets are combined, the degradation rate is no longer consistent and the model is not informed of the prior history when presented with an input pulse voltage.

Once the machine learning model has been trained (e.g., to determine IC features based on the voltage pulse response, in accordance with the offline workflow 510), the online workflow 550 can be deployed and executed. The workflow 550 is configured to estimate IC features (e.g., peaks and extrema of IC curves) in a short period of time (typically a few minutes) for a target LIB cell according to the current operating conditions (e.g., temperature, cell model, etc.) and the voltage response captured as a result of applying a current pulse train to the LIB cell. More particularly, a pulse injection module 560 controllably applies one or more current pulses to terminals of the LIB cell 512 (on which the ML model module 540 was trained offline). The application of the pulse injection produces a voltage response that is converted and formatted into data records representative of the pulse voltage response, with those data records configured to be received as the input data for the input layer of a fully trained ML 570. As noted, any type of ML architecture may be used to implement the ML model for predicting IC features from the voltage response, including the RR and NN architectures discussed above. As can be seen in FIG. 5, the module 540 transfers the parameters (e.g., weight parameters) trained using the ML inputs 530 and the target data 532 (and one or more optimization procedure such as those described herein) to the fully trained ML 570. The ML model 540 can intermittently update the parameters of the model(s) implemented (as more training data becomes available), and once the ML parameters have been updated (e.g., re-optimized), those parameters can be transferred to the fully trained ML 570 to fully or partially replace (adapt) the current online parameters of the fully trained ML 570.

The input data records formed from the voltage response are fed to input layer of the fully trained ML 570. In some embodiment, it may be necessary to partition the data records to several groups of data records that are fed sequentially to the input stage of the fully trained ML 570. In such embodiments, a different ML architecture, such as convolution neural networks, or CNN, may be used. With the input data representative of the voltage response processed by machine learning model implemented, the fully trained ML 570 produces predicted output data, according to the ML parameters computed by the module 540, representative of the IC features. That data is then provided to the quantitative degradation mode characterization analysis module 180 to produce diagnostic/degradation data. The diagnostic/degradation data can be determined according to one or more machine-learning models. For example, separate ML models can be implemented to predict SoH, SoC, SoP, and/or other cell states, based on the input provided to the degradation mode characterization analysis module 180 of FIG. 1 (that input may include records representing of the voltage response, IC data, CDD data, or other data generated or derived in response to application of the pulse). Additionally or alternatively, the diagnostic / degradation data can be determined using a rules-based schema (to map ML data and/or the CDD data to diagnostic and/or degradation parameters), and/or using equations relating IC data, CDD data, and any other data produced through testing procedures applied to the cell, into degradation data.

As can be seen from FIG. 2, in some embodiments, the analysis module 280 (which may be similar to the analysis module 180 of FIG. 1) may also generate the degradation data based on a half-cell models module 270. In such embodiments, composite degradation data may be determined based on the half-cell models' output data and the IC-related data (processed through, for example, the phase transition analysis module 260 to determine IC extrema from the IC curves). Such composite data may be computed according to various formulations such as average of corresponding parameter values, weighted average of values of corresponding parameters, or any other linear or non-linear function that uses degradation parameter values, computed by two (or more) models/processes, to derive a composite degradation parameter value.

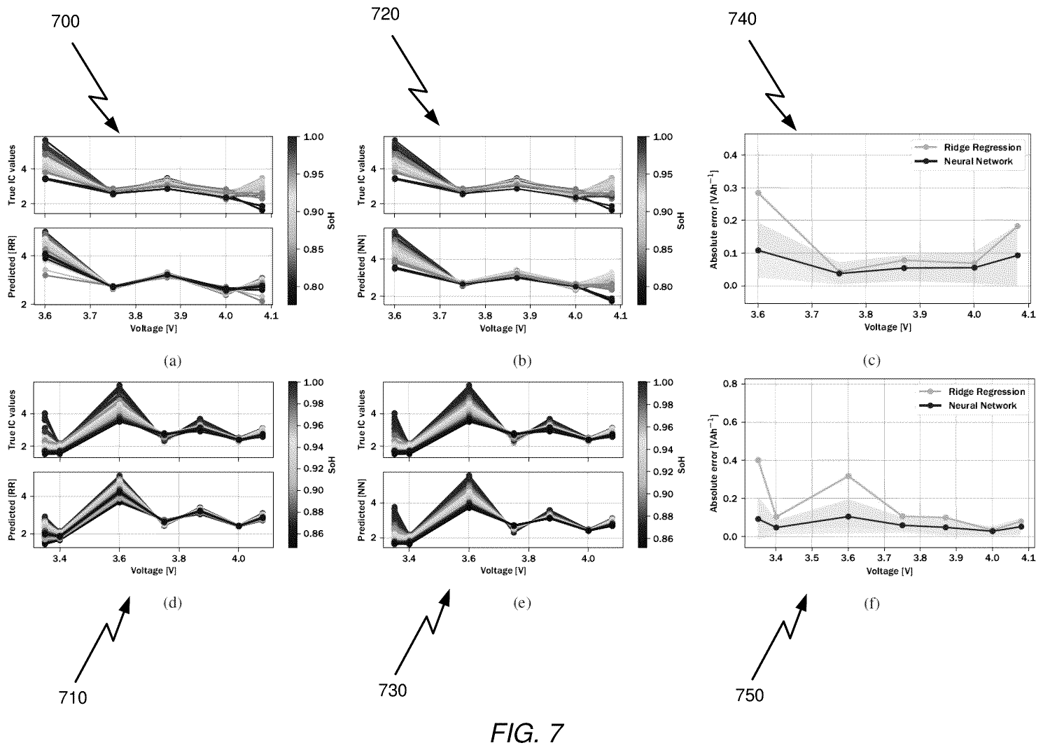

Testing and evaluation of the ML-based implementations to produce IC data based on a voltage response, as described herein, was performed. First, results for IC reconstruction were examined using extrema points, as shown in FIG. 7. Graphs 700 and 710 plot true and reconstructed IC features achieved with the ridge regression (RR) ML model for S1 and S2 stress factors, and graphs 720 and 730 plot true and reconstructed IC features achieved with the neural network (NN) ML model (also for S1 and S2 stress factors, respectively). Finally, graphs 740 and 750 compare the prediction error of RR and NN (for S1 and S2 stress factors, respectively). Qualitatively, the RR model performed well, with the general shape of the extrema points being captured. The NN model, however, offered a significant improvement for both stress factors with much better agreement. Importantly, the NN was less sensitive to voltage. RR suffers from higher prediction error at the voltages corresponding to Peaks 1, 2, and 4. The NN shows less variation in error but there are slight increases at the same peaks. It can be concluded from the high NN performance that pulse voltage is a strong predictor of IC extrema following a complex relationship.

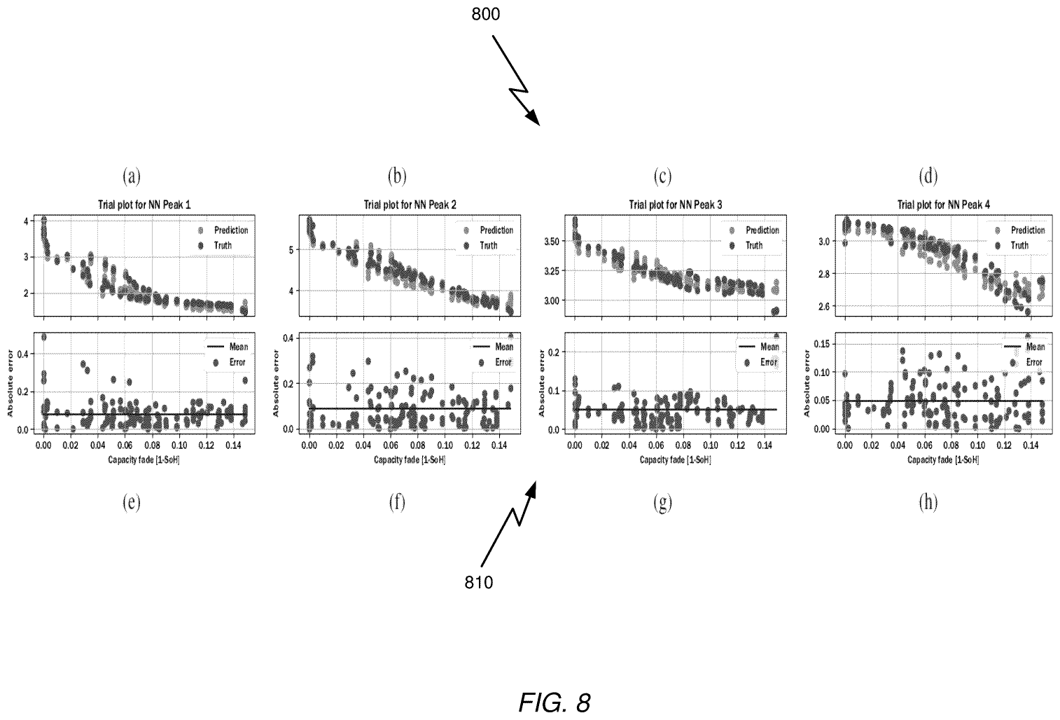

Trial results for individual peaks of S2 are shown in FIG. 8 which includes graphs providing sample prediction results of IC peaks for S2 only, plotted against the level of capacity fade when a pulse was applied. The top row 800 shows RR performance, while the bottom row 810 shows NN performance. From the trial results it became clear that the NN model was more accurate. In particular, the exponential decay observed at low levels of capacity fade is not well-captured using RR. The RR model produces a mostly linear relationship between capacity fade and the peak value. This suggests that there is insufficient information in the pulse voltage for RR to accurately predict the IC peak. In contrast, NN predictions demonstrate strong agreement with the true values. This suggests that transient overpotentials contain sufficient information to predict IC behavior for a given stress factor.

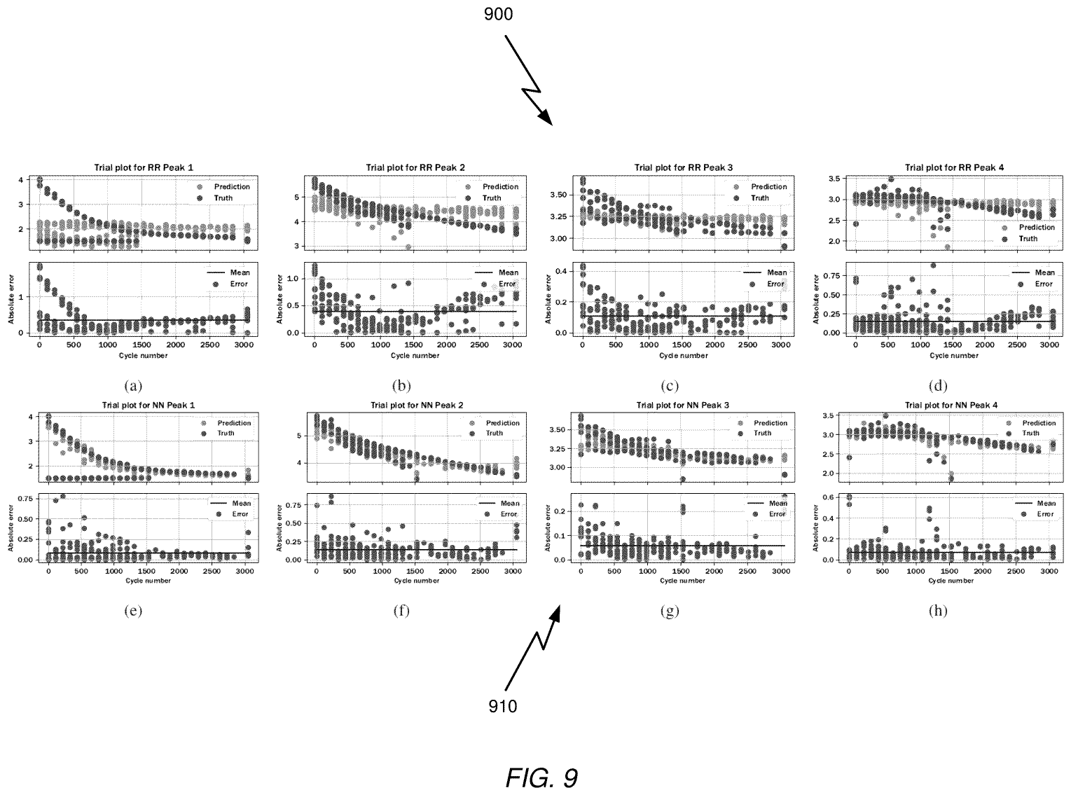

Trial results for individual peaks of the combined datasets of S1 and S2 are shown in FIG. 9, which includes graphs providing sample prediction results of IC peaks when the models are trained on the combined datasets of S1 and S2, with the top two rows 900 providing the results for the RR model, and the bottom two rows 910 providing the results for the NN model. FIG. 9 is organized similarly to FIG. 8, but plotted against cycle number instead of capacity fade to better distinguish the stress factors. For this testing experiment, no information besides the pulse voltage was given. Thus, the models had no knowledge about the prior history of the cell. RR performed worse in this scenario, while the NN accuracy deteriorated only slightly. This is most striking in the results for Peak 1, where the distinct trends between the S1 and S2 peak evolution may be observed. In S1, peak 1 does not exist so it is treated as a constant. Peaks 2 and 4 trends between S1 and S2 also diverge significantly, as shown by the high drop-off rate at 1,500 cycles that corresponds to the S1 cells. The NN model correctly distinguished between the two stress factors using only the pulse voltage. The mean absolute NN model error is nearly half that of the RR model. While the RR's predictions still demonstrated some ability to distinguish between stress factors, its overall accuracy was worse than that of the NN model. This indicates that the accuracy of NN IC peak estimation is maintained regardless of the LIB cell cycling history.

Thus, as shown in FIGS. 5-9, PIAML can be used to accurately reconstruct key IC features in LIB cells. Pseudo-OCV and pulse data from LIB cells cycled with two distinct stress factors were used to train the RR and NN models. NN results indicate that transient overpotentials characterize steady-state dynamics. Pulse perturbation can therefore significantly reduce IC diagnostics time to several minutes (e.g., two (2) minutes), which could inform real-time degradation management strategies.

With reference back to FIG. 2, the incremental capacity data, implemented in some embodiments using one or more machine learning models, represented by the ML module 212 and trained using IC data produced (offline) with the pOCV module 230, generates output data representative of IC data (e.g., IC curve data, or IC extrema data) responsive to the voltage response resulting from the pulse injection (at the module 210). It will be noted that in addition to the voltage response data produced by the cell (not shown in FIG. 2, but shown in FIG. 1) being monitored and analyzed, additional input data may be provided to the module. Such input may include operating conditions for the cell, including the ambient temperature, the specific type of battery being monitored, and so on. The operating conditions input data may be used to either select the proper ML model to be downloaded to the ML engine (e.g., to select a set of ML model parameters associated with the specific operating conditions), or the operating conditions input may combined with the voltage response data and be used as one of the data points that is processed by the ML engine to produce predicted data that accounts for the operating conditions data.

The IC output data (optionally undergoing some preliminary processing at the block 240) is forwarded to a phase transition analysis module configured to determine, at least in part, IC extrema data, based on which degradation mode information (e.g., LAM, LLI, SoH, SoC, etc.) can be determined. The IC data produced by the ML models implemented at 212 may optionally also be forwarded to a half cell models module 270 to independently use the IC data to determine cell performance/degradation information for the lithium-ion battery being analyzed.

It is to be noted that the IC data (as produced offline through pOCV analysis, and subsequently predicted by ML models according to the voltage response to an applied current pulse train) not only yields the cell's SoH, but also encodes information about the positive electrode (PE) and negative electrode (NE) phase transitions. Studies of half-cell models have shown that LAM and LLI may be estimated entirely from the predicted electrode degradation. Underpinning the results from half-cell models is incremental capacity analysis (ICA). As noted, the IC curve is defined as the inverse-derivative of the pOCV with respect to remaining charge capacity, with phase transitions (plateaus in the pOCV) being represented by the IC extrema. Studies of lithium-ion batteries have shown that peak widths of curves determined through IC analysis and DVA (differential voltage analysis) are highly sensitive to LLI and LAM. There are two regimes of degradation: a linear regime where LAM ‘incubates’ and LLI dominates, then rapid capacity loss as LAM dominates. In the proposed frameworks described herein, ML models (be it neural networks or otherwise) are used to bypass parameter identification, thus achieving real-time (or near real-time) implementation. It is further to be noted that alternative methods to parametrize LLI and LAM can also be used. For example, LLI and LAM can be derived from physics-based models (PBM) parameters (although PBM parameters have high computational complexity that could be mitigated using ML). In another example, a single-particle model (SPM) can estimate OCV, and thus obtain degradation modes data, and a pseudo-2D (P2D) model can tracks LAM, diffusivity, and the reaction constant in LIB cells. Parameters from a SPM, P2D, and an ‘improved’ SPM can be used to directly calculate LLI, and LAM (and/or any other degradation parameter). Diffusivity is an important measure of impedance change that can be linked to particle fracture and SEI formation.

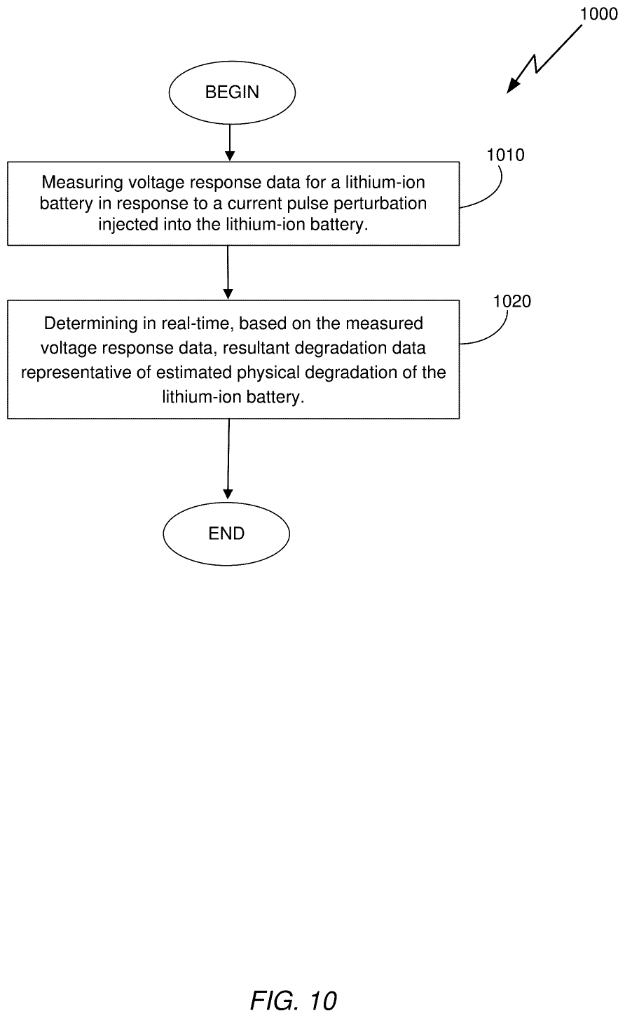

Thus, with reference to FIG. 10, a flowchart of an example procedure 1000 for managing battery performance (in part through monitoring battery degradation) is shown. The procedure 1000 includes measuring 1010 voltage response data for a lithium-ion battery in response to a current pulse perturbation injected into the lithium-ion battery, and determining 1020 in real-time, based on the measured voltage response data, resultant degradation data representative of estimated physical degradation of the lithium-ion battery.

In various examples, the procedure 1000 may further include generating battery diagnostic and management data (e.g., to be presented on a user interface, or used to control operation of the battery or the load to which it is connected) based on the resultant degradation data.

In some examples, determining the resultant degradation data may include determining incremental capacity (IC) behavior for the lithium-ion battery based on the voltage response data provided to at least one trained machine learning (ML) engine implementing an IC prediction model. The at least one ML engine may include one or more of, for example, a neural network (NN)-based implementation and/or or a ridge-regression (RR)-based implementation. It is to be noted that other types of ML architectures or ML techniques may also be used. The at least one ML engine may be trained using input data records, provided to an input stage of the at least one ML engine, prepared from the measured voltage response data, and IC target output data, representing ground truth output for the at least one ML engine, computed based on one or more pseudo-open-circuit voltage (pOCV) tests applied to the lithium-ion battery. Determining the incremental capacity behavior may include determining, based on the measured voltage response data, peaks of IC curves representing the IC behavior for the lithium-ion battery.

In some embodiments, determining the resultant degradation data may include performing overpotential analysis according to a convolution-defined diffusion (CDD) model for the lithium-ion battery based on the measured voltage response data resulting from the current pulse perturbation injected into the lithium-ion battery. In such embodiments, performing the overpotential analysis according to the CDD model for the lithium-ion battery may include determining parameters of a circuit equivalent model, the parameters being representative of electro-chemical attributes of the lithium-ion battery, and deriving one or more voltage components of the voltage response data based on the determined parameters. The procedure may further include determining an impedance change behavior based on the derived one or more voltage components. Determining the parameters representative of the electro-chemical attributes of the lithium-ion battery may include determining one or more of, for example, a series resistance equivalence parameter R₀, charge transfer equivalence parameters R_{N} and C_{N} for N≥1, and/or a diffusion related constant, A_{D}, for the lithium-ion battery at steady state.

The procedure may further include estimating one or more degradation modes for the lithium-ion battery based on the resultant degradation data determined from the measured voltage response data. In some embodiments, estimating the degradation modes may include estimating one or more of, for example, battery impedance change of the lithium-ion battery, loss of lithium inventory (LLI) of the lithium-ion battery, and/or loss of active material (LAM) of the lithium-ion battery. The procedure may further include determining based on, at least in part, the estimated one or more degradation modes one or more of, for example, state of health (SoH) of the lithium-ion battery, and/or state of charge (SoC) for the lithium-ion battery. In various examples, the current pulse perturbation may include one or more rectangle pulses applied to the lithium-ion battery for a duration of up to 3 minutes.

Testing of the full proposed frameworks of FIGS. 1 and 2 was conducted. The experimental setup to test the operation of the framework was similar to the one used to test the approach for deriving IC data using machine learning models. Six Panasonic NCR18650PF nickel-magnesium-cobalt cells were degraded using two stressors. Stressor 1 (S1) cells were cycled from the lower cutoff 2.5 V to mid-voltage 3.7 V at 7° C. and Stressor 2 (S2) cells were cycled from mid-voltage to the upper cutoff 4.2 V at 40° C. Cycling rate was 1 C-rate, 2.7 A. The C/20 pOCV and pulse train were obtained every 100 cycles. Each IC curve corresponded to multiple pulses as a result. Bipolar charge-rest-discharge-rest pulses were applied similarly to the galvanostatic intermittent titration technique, at SoC in the range [0.05, 1] with amplitude 1 C-rate, length 2 min, and sampling rate 10 Hz. There were 363 pulses for S1 and 965 for S2.

Some of the target output required for offline processing (to train machine learning models to predict diagnostic data for the lithium ion battery, including degradation modes) was calculated using traditional modeling techniques. Cell SoH and SoC were obtained through coulomb counting. Integration of the current during the pOCV yields the time-varying maximum cell capacity Q(t) so SoH is given by

$$SoH = \frac{Q ( t )}{{Q}_{0}} ,$$

where Q is capacity at elapsed time t, and Q₀ is the capacity at t=0. For each pulse, the nominal SoC is given by

$$SoC = \frac{q}{Q ( t )} ,$$

where q is the remaining charge capacity. The IC was obtained by taking the inverse derivative of the pOCV Vₚₛ with respect to the instantaneous

$$IC = \frac{dq}{{dV}_{ps}} .$$

A Savitzky-Golay filter was used for smoothing. For each IC curve the peaks and troughs (extrema) points were labelled sequentially. Since the S1 cells do not have the low-voltage peak and trough, S1 labels begin from 3. This is due to low-temperature effects (S2 cells only lose peak 1 after significant degradation). Finally, the voltage harmonics V_{H} are obtained with V_{H}(t)=V(t)−V̅(t), where V is the raw observed pulse voltage and V̅ is the corresponding mean.

Overpotential contribution analysis was performed using the CDD-1RC model discussed herein, which is composed of four (4) equivalent circuit elements that model the ohmic, charge transfer, and diffusion overpotentials, Vₛ, V_{ct}, and V_{D}, such that the terminal voltage is given by V(t)=\hat{V}_{OC}(t)−Vₛ(t)−V_{ct}−V_{D}(t) where \hat{V}_{OC}(t)is the estimated OCV change during the pulse. Circuit elements were fitted through the MATLAB scatter-search global optimization method. To obtain the overpotential contributions, the voltage-time integral product Vₓ during the pulse was calculated for each overpotential x, represented as Vₓ∫₀^{t}^{ₚ}|Vₓ(t)|dt, where tₚ is the pulse length. The OCV variation and hysteresis contribution is given by V_{hys}=∫₀^{t}^{ₚ}|V_{H}(t)|dt−Vₛ−V_{ct}−V_{D}. The contribution fractions are calculated using,

$$contribution fraction = \frac{{V}_{x}}{{V}_{hys} + {V}_{s} + {V}_{ct} + {V}_{D}} .$$

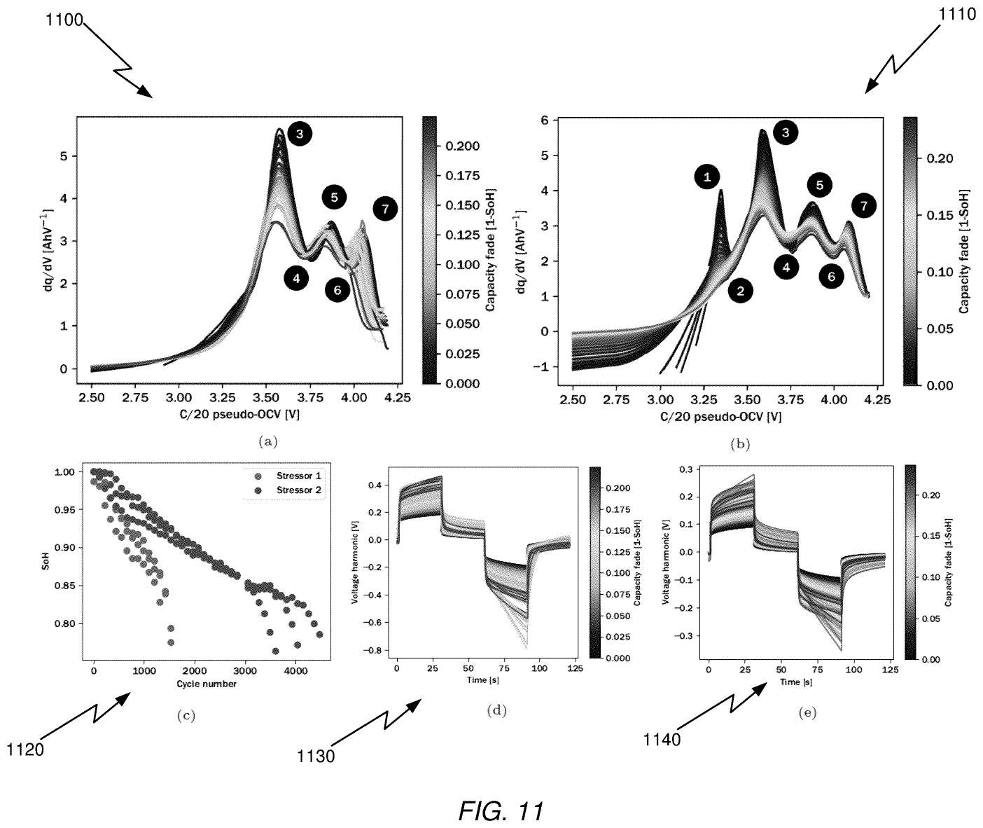

With reference to FIG. 11, graphs plotting the data collected from the six cells are shown. Specifically, graph 1100 shows the IC curves for S1 stress factor, while graph 1110 shows the IC curve for S2 stress factor. From the IC curves, extrema points are extracted (labelled in graphs 1100 and 1110). Graph 1120 illustrates the capacity fade for both stressors, graph 1130 shows the pulse voltage response harmonics for S1, and graph 1140 shows the pulse voltage response for S2. As observed in FIG. 11, S1 cells pass the knee-point at 1500 cycles, while S2 cells degrade much more slowly, only passing the knee at 4000 cycles. Each of the hundreds of pulse voltages has a unique SoH and SoC. Only pulse harmonics are used, as shown in curves 1130 and 1140, that were obtained by subtracting the mean voltage from the raw pulse data. This eliminates effects of the OCV bias and ensures that the data only reflects overpotentials and the OCV or hysteresis variation. It may also improve data regularization.

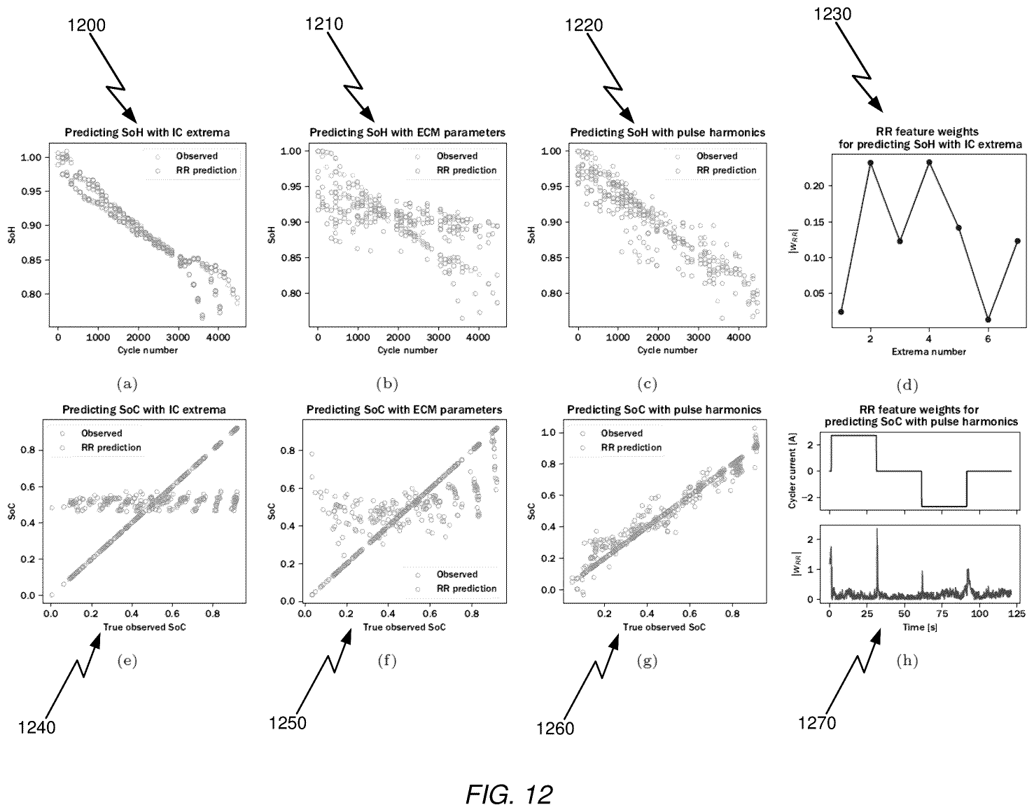

FIG. 12 includes graphs showing ridge regression prediction of SoH based on IC extrema (graph 1200), CDD-1RC (i.e., based on equivalent circuit model) parameters (graph 1210), and pulse harmonics (graph 1220). Ridge regression feature weights for predicting SoH with IC extrema is illustrated in graph 1230. FIG. 12 additionally includes ridge regression prediction of nominal pulse SoC based on Nominal pulse SoC in the S2 dataset using IC extrema (graph 1240), CDD-1RC parameters (graph 1250), and pulse harmonics (graph 1260). Ridge regression feature weights for predicting nominal pulse SoC with IC extrema is illustrated in graph 1270.

As can be seen from the experimental results of FIG. 12, SoH is almost perfectly predicted by the IC extrema. Meanwhile, SoC is predicted by pulse harmonics with 5.3% mean absolute error. Experimental results also show that OCV or hysteresis dynamics during the pulse, coupled with overpotentials, provide a machine learning system (e.g., one implemented as a neural network) sufficient information to learn the LIB cell's degradation modes. Thus, the pulse harmonics have sufficient information to estimate a wide range of degradation metrics and modes, namely, SoC, SoH, overpotentials, and IC features.

The CDD parameter regression results in the graphs 1210 and 1250 also provide useful information. They show that CDD-1RC parameters are correlated with, but are poor predictors of, SoH and/or SoC. This agrees with the known behavior of overpotentials. Since they are identified using the pulse harmonics, it may be surprising that prediction accuracy from CDD parameters decreases significantly compared to direct regression of the pulse voltage. It is possible that the pulse harmonics contain a significant characteristic not directly captured by overpotentials OCV variation.

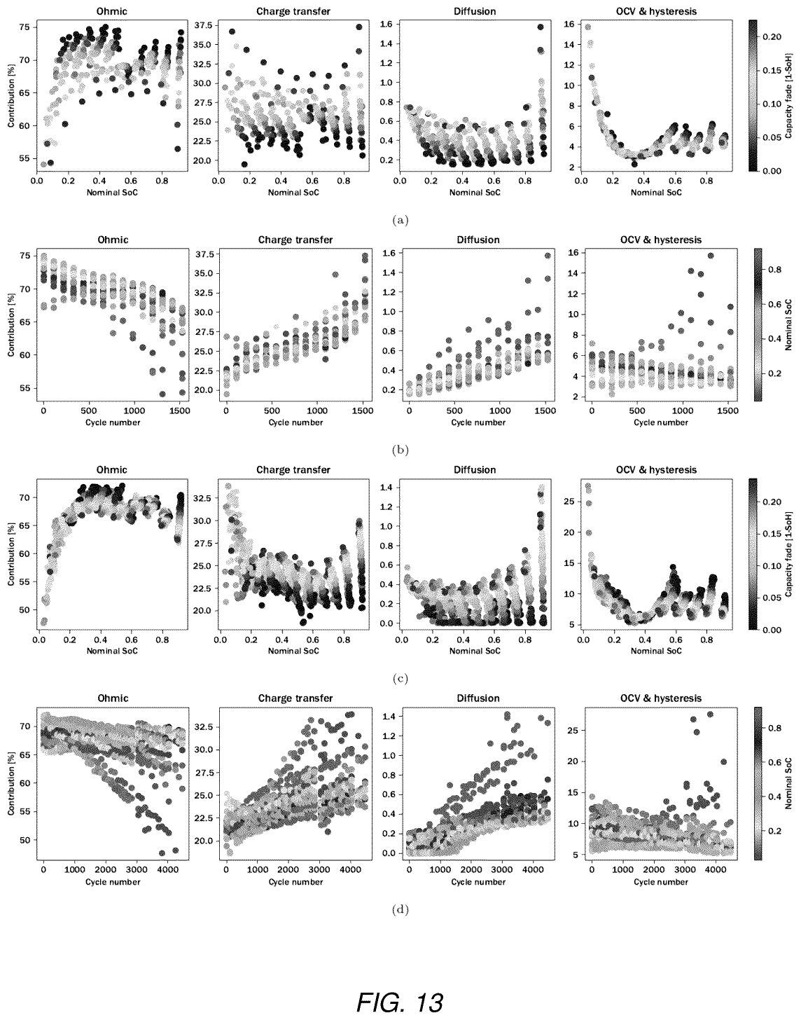

Overpotential contribution percentages for both the S1 and S2 datasets are shown in FIG. 13, plotted against cycle number and SoC (top two rows of the graphs in FIG. 13 correspond to S1 and the bottom two rows correspond to S2). As expected, the ohmic overpotential dominates, followed by charge transfer, OCV variation and hysteresis, and diffusion. As the cells degrade, charge transfer and diffusion become more significant. This could reflect solid-electrolyte layer formation or electrode structural change. At higher SoC, diffusion increases, corresponding to high lithiation in the NE. Charge transfer increases at low SoC, particularly evident in S2, where there is a distinct low-SoC branch beyond cycle 2000. This may reflect high lithiation in the PE impeding ion transport. OCV and hysteresis variation are particularly significant at low SoC and SoH. Peaks in the OCV contribution may reflect IC or differential voltage peaks.

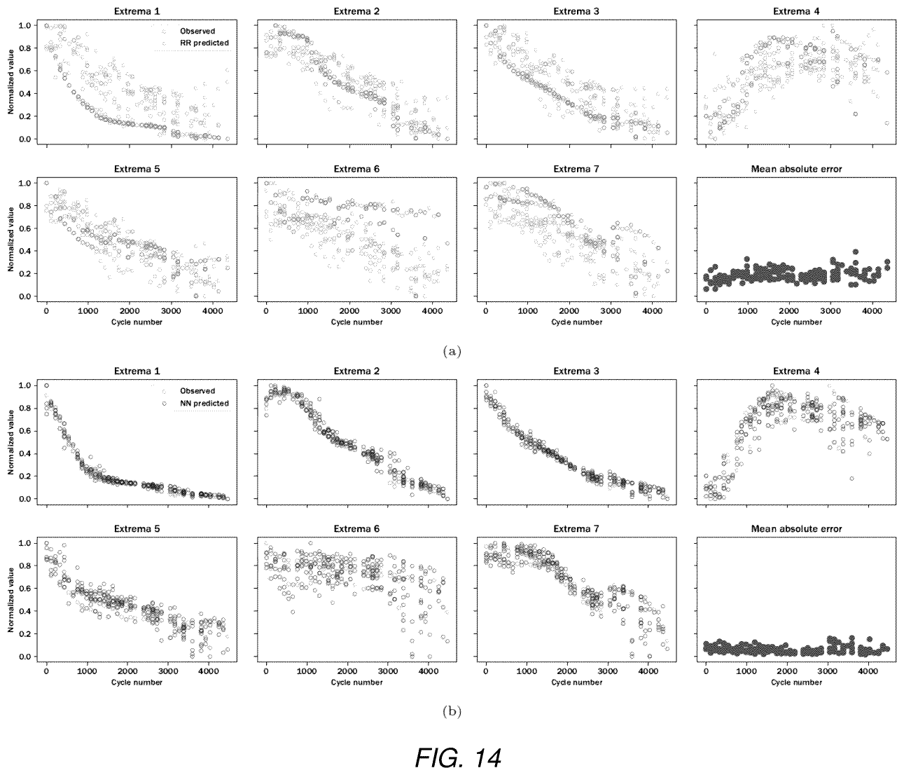

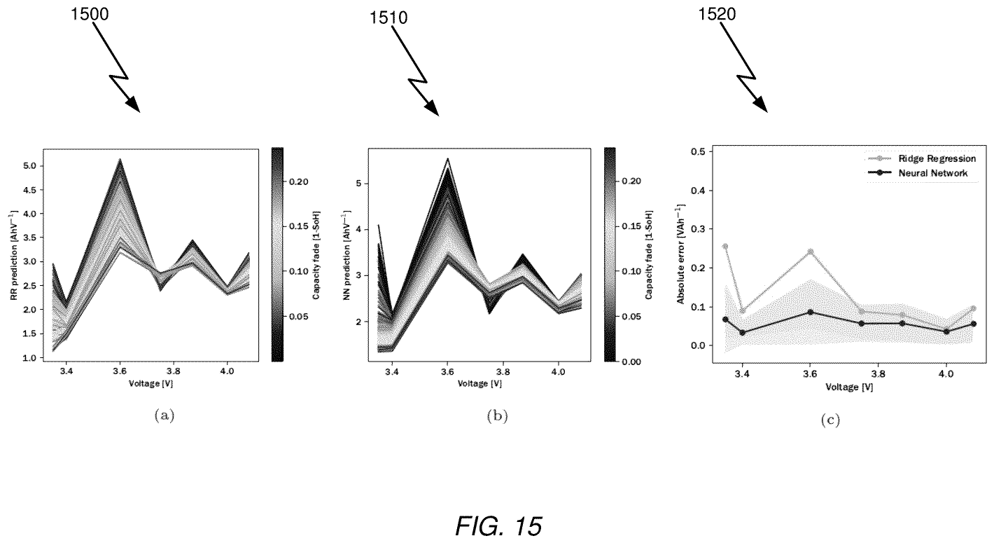

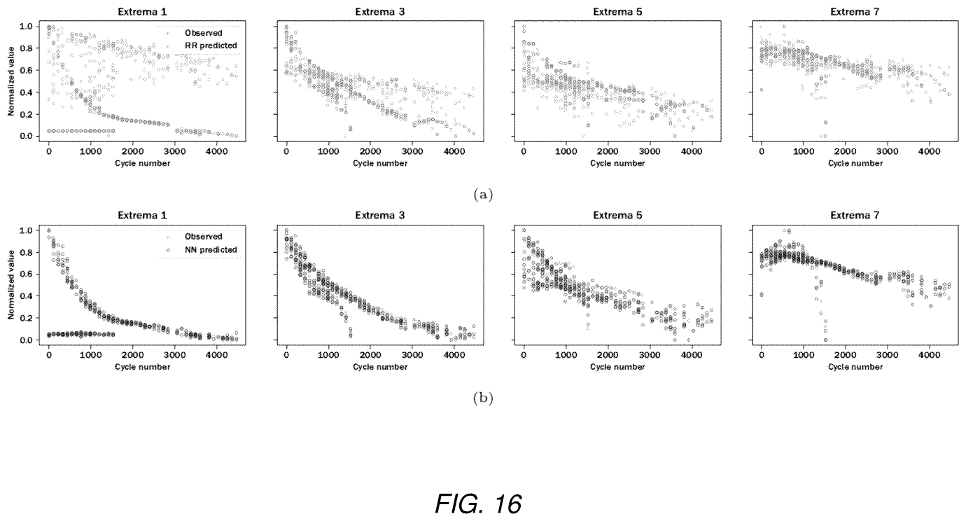

Incremental capacity analysis (ICA) with RR- and NN-based PIAML are shown in FIGS. 14, 15, and 16. Particularly, FIG. 14 includes graphs showing IC extrema identification according to machine learning models (trained on the S2 dataset only) with the top two graph rows of FIG. 14 corresponding to results obtained using a ridge regression machine learning model, and the bottom two rows corresponding to results obtained using a neural network approach. FIG. 15 includes graphs showing reconstructed S2 IC curves using extrema predictions, with graph 1500 showing outputs from a ridge regression ML model, graph 1510 showing outputs from a neural network model, and graph 1520 showing prediction errors under the respective ML models. Finally, FIG. 16 includes graphs showing IC peak identification using a ridge regression ML model (top graphs row) and a neural network ML model (both ML model types were trained on both S1 and S2 datasets).

While the RR model identified a correlation between the pulse and IC extrema, it is unable to accurately reconstruct the extrema points. Yet with an NN model, all of the extrema points can be accurately identified. Comparison of the predicted error in FIG. 15 (the graph 1520) shows that the NN model is consistently more accurate and less sensitive to the peak location. The NN model is also able to distinguish between stressors. Particularly, in FIG. 16 the IC extrema are accurately estimated with NN-PIAML regardless of the cycling history of the cell. Thus, it is likely that there is some signature in the pulse harmonics that the NN model has learnt from. Indeed, as discussed earlier, a likely explanation of why the IC prediction results with NN-PIAML are highly accurate may be provided by the results in FIG. 12. The inner product of the pulse voltage and a constant feature vector is a good predictor of the nominal SoC. Each SoC level therefore leaves a unique signature in the pulse. To obtain the IC curves, ML is, in a sense, tasked with predicting the cell OCV over the entire range of SoC. Whereas RR uses a feature vector to predict a single SoC, the NN model uses multi-dimensional matrix transformations to obtain the entire SoC characteristic. It is hypothesized that OCV or hysteresis dynamics during the pulse, coupled with overpotentials, provide the NN model sufficient information to learn the LIB cell's degradation modes. Thus, the pulse harmonics have sufficient information to estimate a wide range of degradation metrics and modes such as SoC, SoH, overpotentials, and IC features.

Thus, the frameworks described herein use pulse perturbation for diagnosing cell states, ion transport phenomena, and electrode degradation. The CDD ECM and PIAML implemented with RR and NN were applied to large amounts of experimental data to show that a 2 minute pulse can be used to obtain degradation metrics and modes. This characterization ability is likely based on the inherent physical attributes of the pulse harmonics combined with the computational power of a NN.

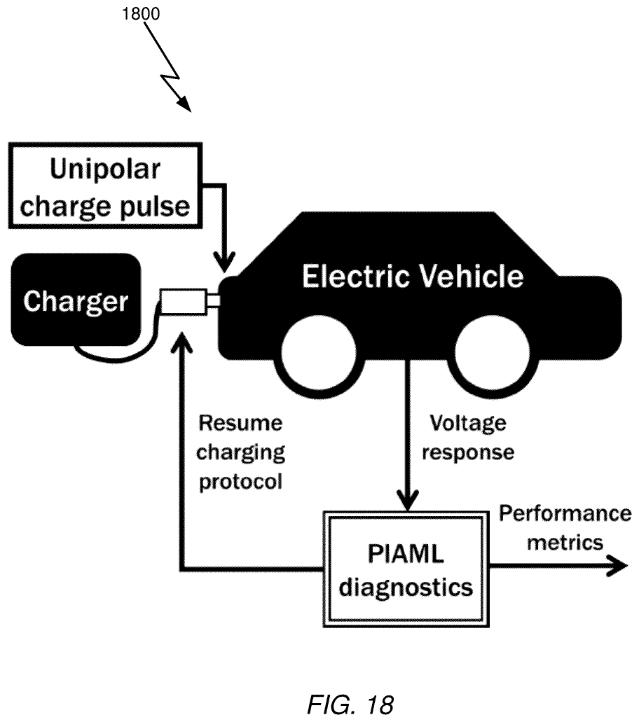

The use of frameworks to manage performance of cells (lithium-ion batteries in the specific examples described herein, although the techniques can be similarly applied to other types of cells) can be used in relation to various applications that use rechargeable cells. One example of such an application, for which PIAML is well-suited for, is electrical vehicle (EV) diagnostics. It has been shown that daily charging profiles are highly predictable based on user profiles. PIAML can thus exploit this predictability to become a reliable and fast daily diagnostics tool. SoH and SoP, unlike SoC, do not need to be continuously tracked, so it is sufficient to schedule the pulse during low-intensity applications. A diagram of a proposed pulse scheduling framework 1800 for an EV is shown in FIG. 18. Once the EV is plugged into the charger, a pulse is applied to the battery pack. The voltage response of each cell is measured and inputted to PIAML diagnostics, which computes the performance metrics within seconds. This can be used to track capacity fade and power fade. PIAML can also provide a high-fidelity reference value for SoC, which can be used to periodically initialize SoC estimation methods such as coulomb counting or Kalman filters. After the pulse is injected, the battery management system allows normal charging to resume. Since charging profiles often last for several hours, any disruption from PIAML perturbation is negligible.

Performing the various techniques and operations described herein may be facilitated by a controller device (e.g., a processor-based computing device). Such a controller device may include a processor-based device such as a computing device, and so forth, that typically includes a central processor unit or a processing core. The device may also include one or more dedicated learning machines (e.g., neural networks) that may be part of the CPU or processing core. In addition to the CPU, the system includes main memory, cache memory and bus interface circuits. The controller device may include a mass storage element, such as a hard drive (solid state hard drive, or other types of hard drive), or flash drive associated with the computer system. The controller device may further include a keyboard, or keypad, or some other user input interface, and a monitor, e.g., an LCD (liquid crystal display) monitor, that may be placed where a user can access them.

The controller device is configured to facilitate, for example, battery performance management, including determination of battery degradation data. The storage device may thus include a computer program product that when executed on the controller device (which, as noted, may be a processor-based device) causes the processor-based device to perform operations to facilitate the implementation of procedures and operations described herein. The controller device may further include peripheral devices to enable input/output functionality. Such peripheral devices may include, for example, flash drive (e.g., a removable flash drive), or a network connection (e.g., implemented using a USB port and/or a wireless transceiver), for downloading related content to the connected system. Such peripheral devices may also be used for downloading software containing computer instructions to enable general operation of the respective system/device. Alternatively and/or additionally, in some embodiments, special purpose logic circuitry, e.g., an FPGA (field programmable gate array), an ASIC (application-specific integrated circuit), a DSP processor, a graphics processing unit (GPU), application processing unit (APU), etc., may be used in the implementations of the controller device. Other modules that may be included with the controller device may include a user interface to provide or receive input and output data. The controller device may include an operating system.

The machine learning systems used in the implementations described herein may be realized using different types of ML architectures, configurations, and/or implementation approaches. For example, neural networks used within the proposed frameworks may include convolutional neural network (CNN), feed-forward neural networks, recurrent neural networks (RNN), etc. Feed-forward networks include one or more layers of nodes (“neurons” or “learning elements”) with connections to one or more portions of the input data. In a feedforward network, the connectivity of the inputs and layers of nodes is such that input data and intermediate data propagate in a forward direction towards the network's output. There are typically no feedback loops or cycles in the configuration/structure of the feed-forward network. Convolutional layers allow a network to efficiently learn features by applying the same learned transformation(s) to subsections of the data. Other examples of learning engine approaches/architectures that may be used include generating an auto-encoder and using a dense layer of the network to correlate with probability for a future event through a support vector machine, constructing a regression or classification neural network model that indicates a specific output from data (based on training reflective of correlation between similar records and the output that is to be identified), vector transformation ML systems, etc. The various learning processes implemented through use of the neural networks may be configured or programmed using TensorFlow (an open-source software library used for machine learning applications such as neural networks). Other programming platforms that can be employed include keras (an open-source neural network library) building blocks, NumPy (an open-source programming library useful for realizing modules to process arrays) building blocks, etc.

Computer programs (also known as programs, software, software applications or code) include machine instructions for a programmable processor, and may be implemented in a high-level procedural and/or object-oriented programming language, and/or in assembly/machine language. As used herein, the term “machine-readable medium” refers to any non-transitory computer program product, apparatus and/or device (e.g., magnetic discs, optical disks, memory, Programmable Logic Devices (PLDs)) used to provide machine instructions and/or data to a programmable processor, including a non-transitory machine-readable medium that receives machine instructions as a machine-readable signal.

In some embodiments, any suitable computer readable media can be used for storing instructions for performing the processes/operations/procedures described herein. For example, in some embodiments computer readable media can be transitory or non-transitory. For example, non-transitory computer readable media can include media such as magnetic media (such as hard disks, floppy disks, etc.), optical media (such as compact discs, digital video discs, Blu-ray discs, etc.), semiconductor media (such as flash memory, electrically programmable read only memory (EPROM), electrically erasable programmable read only Memory (EEPROM), etc.), any suitable media that is not fleeting or not devoid of any semblance of permanence during transmission, and/or any suitable tangible media. As another example, transitory computer readable media can include signals on networks, in wires, conductors, optical fibers, circuits, any suitable media that is fleeting and devoid of any semblance of permanence during transmission, and/or any suitable intangible media.

Although particular embodiments have been disclosed herein in detail, this has been done by way of example for purposes of illustration only, and is not intended to be limiting with respect to the scope of the appended claims, which follow. Features of the disclosed embodiments can be combined, rearranged, etc., within the scope of the invention to produce more embodiments. Some other aspects, advantages, and modifications are considered to be within the scope of the claims provided below. The claims presented are representative of at least some of the embodiments and features disclosed herein. Other unclaimed embodiments and features are also contemplated.

What is claimed is:

1. A method for managing battery performance comprising:
measuring voltage response data for a lithium-ion battery in response to a current pulse perturbation injected into the lithium-ion battery; and
determining in real-time, based on the measured voltage response data, resultant degradation data representative of estimated physical degradation of the lithium-ion battery.

2. The method of claim 1, further comprising:
generating battery diagnostic and management data based on the resultant degradation data.

3. The method of claim 1, wherein determining the resultant degradation data comprises:
determining incremental capacity (IC) behavior for the lithium-ion battery based on the voltage response data provided to at least one trained machine learning (ML) engine implementing an IC prediction model.

4. The method of claim 3, wherein the at least one ML engine includes one or more of: a neural network (NN)-based implementation, or a ridge-regression (RR)-based implementation.

5. The method of claim 3, wherein the at least one ML engine is trained using input training data records, provided to an input stage of the at least one ML engine, prepared from measured training voltage response data resulting from training current pulse perturbations injected into the lithium-ion battery, and IC target output data, representing ground truth output for the at least one ML engine, computed based on one or more pseudo-open-circuit voltage (pOCV) tests applied to the lithium-ion battery.

6. The method of claim 3, wherein determining the incremental capacity behavior comprises:
determining, based on the measured voltage response data, peaks of IC curves representing the IC behavior for the lithium-ion battery.

7. The method of claim 1, wherein determining the resultant degradation data comprises:
performing overpotential analysis according to a convolution-defined diffusion (CDD) model for the lithium-ion battery based on the measured voltage response data resulting from the current pulse perturbation injected into the lithium-ion battery.

8. The method of claim 7, wherein performing the overpotential analysis according to the CDD model for the lithium-ion battery comprises:
determining parameters of a circuit equivalent model, the parameters being representative of electro-chemical attributes of the lithium-ion battery; and
deriving one or more voltage components of the voltage response data based on the determined parameters.

9. The method of claim 8, further comprising:
determining an impedance change behavior based on the derived one or more voltage components.

10. The method of claim 8, wherein determining the parameters representative of the electro-chemical attributes of the lithium-ion battery comprises determining one or more of: a series resistance equivalence parameter R₀, charge transfer equivalence parameters R_{N} and C_{N} for N≥1, and a diffusion related constant, A_{D}, for the lithium-ion battery at steady state.

11. The method of claim 1, further comprising:
estimating one or more degradation modes for the lithium-ion battery based on the resultant degradation data determined from the measured voltage response data.

12. The method of claim 11, wherein estimating the one or more degradation modes comprises estimating one or more of: battery impedance change of the lithium-ion battery, loss of lithium inventory (LLI) of the lithium-ion battery, or loss of active material (LAM) of the lithium-ion battery.

13. The method of claim 12, further comprising:
determining based on, at least in part, the estimated one or more degradation modes one or more of: state of health (SoH) of the lithium-ion battery, or state of charge (SoC) for the lithium-ion battery.

14. The method of claim 1, wherein the current pulse perturbation comprises one or more rectangle pulses applied to the lithium-ion battery for a duration of up to 3 minutes.

15. A battery performance management system comprising:
a sensor to measure voltage response data for a lithium-ion battery in response to a current pulse perturbation injected into the lithium-ion battery; and
a processor-based controller, coupled to the sensor, configured to determine in real-time, based on the measured voltage response data, resultant degradation data representative of estimated physical degradation of the lithium-ion battery.

16. The system of claim 15, wherein the processor-based controller configured to determine the resultant degradation data is configured to:
determine incremental capacity (IC) behavior for the lithium-ion battery based on the voltage response data provided to at least one trained machine learning (ML) engine implementing an IC prediction model.

17. The system of claim 16, wherein the at least one ML engine is trained using input training data records, provided to an input stage of the at least one ML engine, prepared from measured training voltage response data resulting from training current pulse perturbations injected into the lithium-ion battery, and IC target output data, representing ground truth output for the at least one ML engine, computed based on one or more pseudo-open-circuit voltage (pOCV) tests applied to the lithium-ion battery.

18. The system of claim 16, wherein the processor-based controller configured to determine the incremental capacity behavior is configured to determine, based on the measured voltage response data, peaks of IC curves representing the IC behavior for the lithium-ion battery.

19. The system of claim 15, wherein the processor-based controller configured to determine the resultant degradation data is configured to:
perform overpotential analysis according to a convolution-defined diffusion (CDD) model for the lithium-ion battery based on the measured voltage response data resulting from the current pulse perturbation injected into the lithium-ion battery, including to:
determine parameters of a circuit equivalent model, the parameters being representative of electro-chemical attributes of the lithium-ion battery; and
derive one or more voltage components of the voltage response data based on the determined parameters.

20. A non-transitory computer readable media comprising computer instructions executable on a processor-based device to:
measure voltage response data for a lithium-ion battery in response to a current pulse perturbation injected into the lithium-ion battery; and
determine in real-time, based on the measured voltage response data, resultant degradation data representative of estimated physical degradation of the lithium-ion battery.
